(19) United States
(12) Patent Application Publication
(10) Pub. No.: US 2025/0202432 A1
(43) Pub. Date: Jun. 19, 2025

(54) TRACKER MODULE AND COMMUNICATION DEVICE

(71) Applicant: Murata Manufacturing Co., Ltd., Nagaokakyo-shi (JP)

(72) Inventors: Takeshi KOGURE, Nagaokakyo-shi (JP); Muneharu KATO, Nagaokakyo-shi (JP); Toshiki MATSUI, Nagaokakyo-shi (JP)

(21) Appl. No.: 19/072,394

(22) Filed: Mar. 6, 2025

Related U.S. Application Data
(63) Continuation of application No. PCT/JP2023/033624, filed on Sep. 14, 2023.

(30) Foreign Application Priority Data
Sep. 29, 2022 (JP) 2022-155901

(51) Int. Cl. H03F 1/02; H03F 3/24

(52) U.S. Cl. CPC H03F 1/0233; H03F 3/245; H03F 2200/105; H03F 2200/451

(57) ABSTRACT

A tracker module is provided that includes a module laminate separate from a substrate on which a switch is disposed that is included in a pre-regulator circuit configured to convert an input voltage into a regulated voltage; a switched-capacitor circuit configured to generate a plurality of discrete voltages based on the regulated voltage; and a supply modulator configured to selectively output at least one of the plurality of discrete voltages to an amplifier. A switch and a capacitor included in the switched-capacitor circuit and a switch included in the supply modulator are disposed on the module laminate.

### CROSS REFERENCE TO RELATED APPLICATIONS

This application is a continuation of International Application No. PCT/JP2023/033624, filed Sep. 14, 2023, which claims priority to Japanese Patent Application No. 2022-155901, filed Sep. 29, 2022, the entire contents of each of which are hereby incorporated by reference.

### TECHNICAL FIELD

The present disclosure relates to a tracker module and a communication device.

### BACKGROUND

U.S. Pat. No. 9,755,672 (hereinafter “Patent Document 1”) discloses a power supply modulation circuit (e.g., a envelope tracking system) that supplies a power supply voltage to a power amplifier circuit based on an envelope signal. The power supply modulation circuit includes: a magnetic converter circuit (magnetic regulation stage: pre-regulator circuit) that converts a voltage; a switched-capacitor circuit (switched-capacitor voltage balancer stage) that generates, from the voltage, a plurality of voltages having different voltage levels; and a supply modulator (output switching stage) that selects and outputs at least one of the plurality of voltages. The magnetic converter circuit includes switches and power inductors; the switched-capacitor circuit includes switches and capacitors; and the supply modulator includes switches.

However, in the configuration of the power supply modulation circuit of Patent Document 1, since the switched-capacitor circuit generates a plurality of voltages having different voltage levels based on a regulated voltage outputted from the pre-regulator circuit, the voltage output characteristics of the pre-regulator circuit and the supply modulator may deteriorate due to heat generation, and the efficiency of the power amplifier circuit may deteriorate.

### SUMMARY

In view of the foregoing, the exemplary aspects of the present disclosure provide a tracker module and a communication device that suppresses the efficiency deterioration of a power amplifier circuit.

In an exemplary aspect, a tracker module is provided that includes a module laminate separate from a substrate on which a switch included in a pre-regulator circuit is disposed; a switched-capacitor circuit configured to generate a plurality of discrete voltages based on a regulated voltage provided by the pre-regulator circuit; and a supply modulator configured to selectively output at least one of the plurality of discrete voltages to an amplifier. A switch and a capacitor included in the switched-capacitor circuit and a switch included in the supply modulator are disposed on the module laminate.

In another exemplary aspect, a tracker module is provided that includes a switched-capacitor circuit configured to generate a plurality of discrete voltages based on a first regulated voltage regulated by a first converter; a supply modulator configured to selectively output at least one of the plurality of discrete voltages to an amplifier; a module laminate on which a switch and a capacitor included in the switched-capacitor circuit and a switch included in the supply modulator are disposed; and an externally connectable first regulated voltage input terminal that is disposed on the module laminate and that receives the first regulated voltage.

According to the exemplary aspects of the present disclosure, a tracker module and a communication device are provided that suppress the efficiency deterioration of a power amplifier circuit.

### BRIEF DESCRIPTION OF DRAWINGS

FIG. 1A is a graph showing an example of the transition of a power supply voltage in an APT (Average Power Tracking) mode.

FIG. 1B is a graph showing an example of the transition of a power supply voltage in an analog ET mode.

FIG. 1C is a graph showing an example of the transition of a power supply voltage in a digital ET mode.

FIG. 2 is a circuit configuration diagram of a communication device according to an exemplary embodiment.

FIG. 3 is a circuit configuration diagram of a pre-regulator circuit, a switched-capacitor circuit, a supply modulator, and a filter circuit according to the exemplary embodiment.

FIG. 4 is a circuit configuration diagram of a digital control circuit according to the exemplary embodiment.

FIG. 5 is a configuration diagram of a tracker module and its peripheral circuits according to the exemplary embodiment.

FIG. 6A is a plan view of the tracker module according to the exemplary embodiment.

FIG. 6B is a plan view of the tracker module according to the exemplary embodiment.

FIG. 6C is a cross-sectional view of the tracker module according to the exemplary embodiment.

FIG. 7A is a plan view of a tracker module according to Variation 1 of the exemplary embodiment.

FIG. 7B is a plan view of the tracker module according to Variation 1 of the exemplary embodiment.

FIG. 7C is a cross-sectional view of the tracker module according to Variation 1 of the exemplary embodiment.

FIG. 8A is a plan view of a tracker module according to Variation 2 of the exemplary embodiment.

FIG. 8B is a plan view of the tracker module according to Variation 2 of the exemplary embodiment.

FIG. 8C is a cross-sectional view of the tracker module according to Variation 2 of the exemplary embodiment.

FIG. 9 is a circuit configuration diagram of a tracker module and its peripheral circuits according to Variation 3 of the exemplary embodiment.

FIG. 10 is a plan view of the tracker module according to Variation 3 of the exemplary embodiment.

FIG. 11 is an implementation configuration diagram of the communication device according to the exemplary embodiment.

### DETAILED DESCRIPTION OF EMBODIMENTS

Exemplary embodiments of the present disclosure will be described in detail below with reference to the drawings. In general, the embodiments described below are comprehensive or specific examples. The numerical values, shapes, materials, components, arrangement of components, connection forms, and the like shown in the following embodiments are examples and are not intended to limit the present disclosure.

For purposes of this disclosure, each drawing is schematic with emphasis, omissions, or proportion adjustments as appropriate to illustrate the exemplary aspects and is not necessarily strictly illustrated, and shapes, positional relationships, and proportions may differ from actual ones. In each drawing, substantially identical components are denoted by the same reference signs, and duplicate descriptions may be omitted or simplified.

In circuit configurations of the present disclosure, the term “connected” includes not only being directly connected at a connection terminal and/or a wiring conductor, but also being electrically connected via another circuit element. The expression “connected between A and B” can be considered to be “connected between A and B and to both A and B”.

In circuit configurations of the present disclosure, the term “connected” includes not only being directly connected at a connection terminal and/or a wiring conductor, but also being electrically connected via another circuit element. The expression “directly connected” can be considered to be “directly connected at a connection terminal and/or a wiring conductor without another circuit element interposed therebetween”. The expression “connected between A and B” can be considered to be “connected between A and B and to both A and B”.

In component arrangements of the present disclosure, the expression “a component is disposed on the substrate” includes a state in which the component is disposed on a main surface of the substrate and a state in which the component is disposed in the substrate. The expression “a component is disposed on the main surface of the substrate” includes a state in which the component is disposed above the main surface without being in contact with the main surface (for example, the component is stacked on another component disposed in contact with the main surface) in addition to a state in which the component is disposed in contact with the main surface of the substrate. The expression “a component is disposed on the main surface of the substrate” may also include a state in which the component is disposed in a recess formed in the main surface. The expression “a component is disposed in the substrate” includes a state in which the entire component is disposed between both main surfaces of the substrate but a portion of the component is not covered by the substrate and a state in which only a portion of the component is disposed in the substrate, in addition to a state in which the component is encapsulated in the module laminate.

In the following drawings, the x-axis and the y-axis are axes orthogonal to each other on a plane parallel to a main surface of a module laminate. Specifically, when a module laminate has a rectangular shape in plan view, the x-axis is parallel to a first side of the module laminate, and the y-axis is parallel to a second side orthogonal to the first side of the module laminate. The z-axis is an axis perpendicular to the main surface of the module laminate, and the positive direction of the z-axis indicates an upward direction and the negative direction of the z-axis indicates a downward direction.

Further, in component arrangements of the present disclosure, the expression “the module laminate is viewed in plan view” can refer to viewing an object orthographically projected onto the xy plane from the positive side of the z-axis. The expression “A overlaps with B in plan view” can be considered to mean that at least a portion of a region obtained by orthographically projecting A onto the xy plane overlaps with at least a portion of a region obtained by orthographically projecting B onto the xy plane. Further, the expression “A is disposed between B and C” can be considered to mean that at least one of a plurality of line segments connecting any point in B and any point in C passes through A.

Further, terms indicating relationships between elements, such as “parallel” and “orthogonal”, and terms indicating the shapes of elements, such as “rectangular”, as well as numerical ranges do not represent only strict meanings, but also include substantially equivalent ranges, for example, with errors of several percent.

In the present disclosure, the term “terminal” can refer to a point at which a conductor in an element terminates. It is also noted that when the impedance of a conductor between elements is sufficiently low, the terminal is also interpreted as any point on the conductor between the elements or as the entire conductor, instead of being interpreted only as a single point.

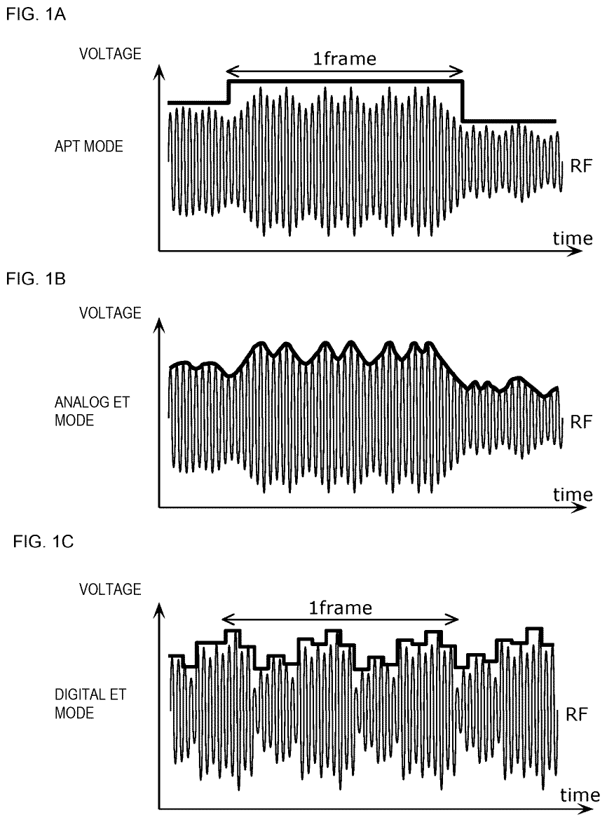

First, a tracking mode, which supplies a power amplifier with a variable power supply voltage dynamically regulated over time based on a radio frequency signal, will be described as a technology for amplifying a radio frequency signal with high efficiency. A tracking mode is a mode that dynamically regulates a power supply voltage applied to an amplifier circuit. There are several types of tracking modes. For purposes of this disclosure, an APT (average power tracking) mode and an ET (envelope tracking) mode (including an analog ET mode and a digital ET mode) will be described with reference to FIGS. 1A to 1C. It is noted that in FIGS. 1A to 1C, the horizontal axis represents time and the vertical axis represents voltage. The thick solid line represents a power supply voltage and the thin solid line (e.g., a waveform) represents a modulated signal.

FIG. 1A is a graph showing an example of the transition of a power supply voltage in an APT mode. In the APT mode, the power supply voltage is changed to a plurality of discrete voltage levels in units of one frame. As a result, the power supply voltage signal forms a rectangular wave. In the APT mode, the voltage level of the power supply voltage is determined based on the average output power. Note that, in the APT mode, the voltage level may also change in units smaller than one frame (for example, sub-frame, slot, or symbol). According to an exemplary aspect, when the voltage level changes in units of symbol, APT is sometimes called SPT (symbol power tracking).

For purposes of this disclosure, a frame is a unit of a radio frequency signal having a length of 10 milliseconds, and includes 10 sub-frames. A sub-frame is a unit of a radio frequency signal having a length of 1 millisecond, and includes 2 slots. A slot is a unit of a radio frequency signal having a length of 0.5 milliseconds, and includes 6 symbols. A symbol is a unit of a radio frequency signal having a length of 71 microseconds, and includes a CP (cyclic prefix).

In an SPT mode, the level of the power supply voltage is modulated in units of 1 symbol. At this time, the voltage level is changed in the section of the CP. For example, in a first symbol, the voltage level is changed to a higher voltage level in the CP, and in a second symbol, the voltage level is changed to a lower voltage level in the CP. It is noted that, in subsequent symbol(s), the voltage level does not have to be changed. The level of the power supply voltage can be modulated based on the data signal in the section of each symbol.

In the present disclosure, the APT mode includes the SPT mode, and APT modules include a module that supplies the power supply voltage to a PA module in the SPT mode.

FIG. 1B is a graph showing an example of the transition of a power supply voltage in an analog ET mode. The analog ET mode is an example of an existing ET mode. As shown in FIG. 1B, in the analog ET mode, the envelope of the modulated signal is tracked by continuously changing the power supply voltage. In the analog ET mode, the power supply voltage is determined based on an envelope signal.

According to an exemplary aspect, the envelope signal is a signal that indicates the envelope of the modulated signal. The envelope value is expressed, for example, by the square root of (I²+Q²). For purposes of this disclosure, (I, Q) represents a constellation point. The constellation point is a point that represents a signal modulated by digital modulation on a constellation diagram. (I, Q) is determined by a BBIC (baseband integrated circuit) based on transmission information, for example.

FIG. 1C is a graph showing an example of the transition of a power supply voltage in a digital ET mode. As shown in FIG. 1C, in the digital ET mode, the envelope of the modulated signal is tracked by changing the power supply voltage to a plurality of discrete voltage levels in one frame. As a result, the power supply voltage signal forms a rectangular wave. In the digital ET mode, a power supply voltage level is selected from the plurality of discrete voltage levels based on the envelope signal or set based on the envelope signal.

### Exemplary Embodiment

An exemplary embodiment will be described below. A communication device 6 according to the present embodiment corresponds to UE (user equipment) in a cellular network; typical examples of the communication device 6 include a mobile phone, a smartphone, a tablet computer, a wearable device, and the like. The communication device 6 may also be an IoT (internet of Things) sensor device, a medical/healthcare device, a car, a UAV (unmanned aerial vehicle) (e.g., a “drone”), or an AGV (automated guided vehicle). The communication device 6 may also be configured as a BS (base station) in a cellular network.

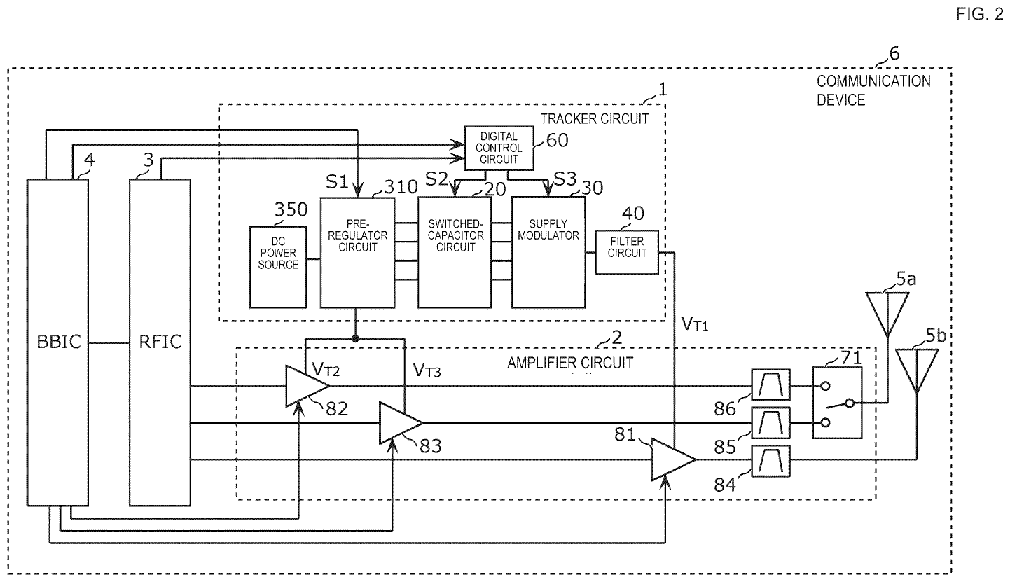

The circuit configurations of the communication device 6, a tracker circuit 1, and an amplifier circuit 2 according to the present embodiment will be described with reference to FIG. 2. FIG. 2 is a circuit configuration diagram of the communication device 6 according to the present embodiment.

Note that FIG. 2 shows an exemplary circuit configuration, and the communication device 6, the tracker circuit 1, and the amplifier circuit 2 can be implemented using any of a wide variety of circuit implementations and circuit techniques. Therefore, the descriptions of the communication device 6, the tracker circuit 1, and the amplifier circuit 2 provided below are exemplary and not so limited.

### [1.1 Circuit Configuration of Communication Device 6]

First, the communication device 6 according to the present embodiment will be described with reference to FIG. 2. The communication device 6 includes the tracker circuit 1, the amplifier circuit 2, an RFIC (radio frequency integrated circuit) 3, a BBIC 4, and antennas 5a and 5b.

The tracker circuit 1 can supply a plurality of discrete power supply voltages V_{T1} based on a tracking mode to the amplifier circuit 2. A digital ET mode can be used as the tracking mode, but the tracking mode is not limited to a digital ET mode.

As shown in FIG. 2, the tracker circuit 1 includes a pre-regulator circuit 310, a switched-capacitor circuit 20, a supply modulator 30, a filter circuit 40, a DC power source 350, and a digital control circuit 60.

The pre-regulator circuit 310 includes a power inductor and switches. The power inductor is an inductor used for raising and/or lowering a DC voltage. The power inductor is series-connected to a DC path. The power inductor may be connected (e.g., disposed in parallel) between a series path and the ground. The pre-regulator circuit 310 can convert an input voltage to a regulated voltage using the power inductor. Such a pre-regulator circuit 310 is sometimes called a magnetic regulator or a converter.

The switched-capacitor circuit 20 includes a plurality of capacitors and a plurality of switches and is configured to generate a plurality of discrete voltages, each having a respective one of a plurality of discrete voltage levels, based on the regulated voltage from the pre-regulator circuit 310. For purposes of this disclosure, the switched-capacitor circuit 20 may sometimes be referred to as a switched-capacitor voltage balancer. The switched-capacitor circuit 20 is controlled based on a digital control signal.

The supply modulator 30 is configured to selectively output at least one of the plurality of discrete voltages generated by the switched-capacitor circuit 20 to the amplifier circuit 2. The supply modulator 30 is controlled based on a digital control signal.

The filter circuit 40 can attenuate noise components from the signals (the plurality of discrete voltages) outputted from the supply modulator 30.

The DC power source 350 can supply a DC voltage to the pre-regulator circuit 310. A rechargeable battery, for example, can be used as the DC power source 350, but the DC power source 350 is not limited to a rechargeable battery.

The digital control circuit 60 can control the switched-capacitor circuit 20 and the supply modulator 30 based on digital control signals from the RFIC 3 and the BBIC 4.

In another exemplary aspect, the tracker circuit 1 may not include at least one of the pre-regulator circuit 310, the switched-capacitor circuit 20, the supply modulator 30, the filter circuit 40, the DC power source 350, and the digital control circuit 60. For example, the tracker circuit 1 does not include the DC power source 350 in an exemplary aspect. Further, any combination of the switched-capacitor circuit 20, the supply modulator 30, and the filter circuit 40 may be integrated into a single circuit in an exemplary aspect.

The amplifier circuit 2 includes power amplifiers 81, 82, and 83, filters 84, 85, and 86, and a switch 71.

The power amplifier 82 is an example of a first power amplifier, and is connected between the RFIC 3 and the filter 86. Further, the power amplifier 82 is connected to the pre-regulator circuit 310 without the switched-capacitor circuit 20, the supply modulator 30, or the filter circuit 40 interposed therebetween. The power amplifier 82 can amplify a radio frequency signal of a band A received from the RFIC 3 by using a power supply voltage V_{T2} received from the pre-regulator circuit 310.

The power amplifier 83 is an example of the first power amplifier, and is connected between the RFIC 3 and the filter 85. Further, the power amplifier 83 is connected to the pre-regulator circuit 310 without the switched-capacitor circuit 20, the supply modulator 30, or the filter circuit 40 interposed therebetween. The power amplifier 83 can amplify a radio frequency signal of a band B received from the RFIC 3 by using a power supply voltage V_{T3} received from the pre-regulator circuit 310.

The power amplifier 82 can receive, for example, the power supply voltage V_{T2} in an APT mode from the pre-regulator circuit 310. The power amplifier 83 can receive, for example, the power supply voltage V_{T3} in an APT mode from the pre-regulator circuit 310.

The power amplifier 81 is an example of a second power amplifier, and is connected between the RFIC 3 and the filter 84. Further, the power amplifier 81 is connected to the filter circuit 40. The power amplifier 81 can amplify a radio frequency signal of a band C received from the RFIC 3 by using a power supply voltage Vri received from the supply modulator 30 and the filter circuit 40.

The power amplifier 81 can receive, for example, the power supply voltage V_{T1} in a digital ET mode from the tracker circuit 1.

The filter 86 is connected between the power amplifier 82 and the antenna 5a. The filter 86 is a band pass filter with a pass band that includes the band A. The filter 85 is connected between the power amplifier 83 and the antenna 5a. The filter 85 is a band pass filter with a pass band that includes the band B. The filter 84 is connected between the power amplifier 81 and the antenna 5b. The filter 84 is a band pass filter with a pass band that includes the band C.

The band A, the band B, and the band C are frequency bands for a communication system constructed using a radio access technology (RAT), and are predefined by a standardizing body or the like, such as the 3rd Generation Partnership Project (3GPP)® and the Institute of Electrical and Electronics Engineers (IEEE). Examples of the communication system include a 5th Generation New Radio (5GNR) system, a Long Term Evolution (LTE) system, and a Wireless Local Area Network (WLAN) system.

In an exemplary aspect, the band A is included, for example, in a low band group (LB group: 600 MHz to 1 GHZ). The band B is included, for example, in a middle-high band group (MHB group: 1.5 to 2.8 GHZ). The band C is included, for example, in an ultra-high band group (UHB group: 3300 to 5000 MHz).

The switch 71 includes a terminal connected to the filter 86, a terminal connected to the filter 85, and a terminal connected to the antenna 5a. The switch 71 can switch between connection of the filter 86 to the antenna 5a and connection of the filter 85 to the antenna 5a.

The RFIC 3 is an example of a signal processing circuit for processing radio frequency signals. Specifically, the RFIC 3 can be configured to perform signal processing on a transmission signal inputted from the BBIC 4 by up-converting or the like, and supplies a radio frequency transmission signal generated by performing the signal processing to the power amplifiers 81 to 83. The RFIC 3 has a control unit that controls the tracker circuit 1. It is noted that some or all of the functions and operations of the control unit of the RFIC 3 may be implemented outside the RFIC 3 in an exemplary aspect.

The BBIC 4 is a circuit that is configured to perform signal processing using a baseband band lower than the frequency of the radio frequency signal transmitted through the amplifier circuit 2. The BBIC 4 also has a control unit that controls the tracker circuit 1. It is noted that some or all of the functions and operations of the control unit of the BBIC 4 may be implemented outside the BBIC 4 in an exemplary aspect.

The antenna 5a outputs the transmission signal of the band A inputted from the power amplifier 82 via the filter 86 and the transmission signal of the band B inputted from the power amplifier 83 via the filter 85. The antenna 5b outputs the transmission signal of the band C inputted from the power amplifier 81 via the filter 84. Note that the antennas 5a and 5b may be a single antenna connected to the filters 84 to 86 via a switch circuit. Further, the antennas 5a and 5b may not be included in the communication device 6 in an alternative aspect.

Note that the circuit configuration of the communication device 6 shown in FIG. 2 is an example, and is not limited to such an example.

### [1.2 Circuit Configuration of Tracker Circuit 1]

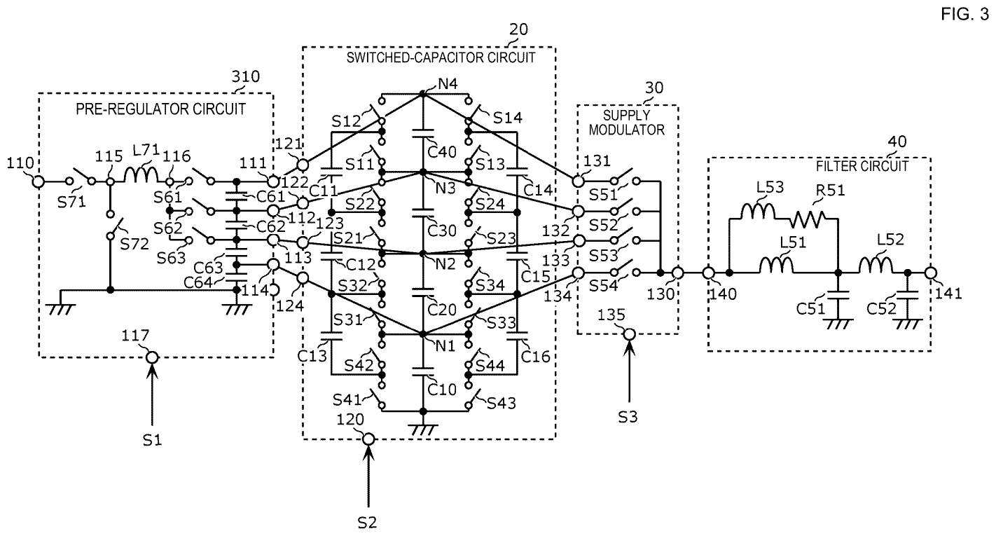

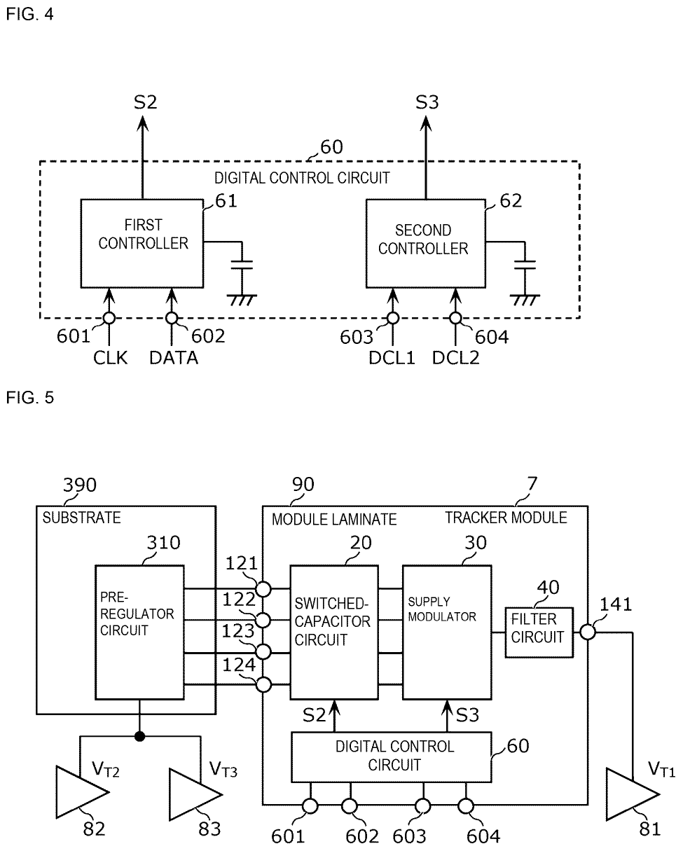

Next, the circuit configurations of the pre-regulator circuit 310, the switched-capacitor circuit 20, the supply modulator 30, the filter circuit 40, and the digital control circuit 60 included in the tracker circuit 1 will be described with reference to FIGS. 3 and 4.

FIG. 3 is a circuit configuration diagram of the pre-regulator circuit 310, the switched-capacitor circuit 20, the supply modulator 30, and the filter circuit 40 according to the present embodiment. FIG. 4 is a circuit configuration diagram of the digital control circuit 60 according to the present embodiment.

FIGS. 3 and 4 show exemplary circuit configurations, and the pre-regulator circuit 310, the switched-capacitor circuit 20, the supply modulator 30, the filter circuit 40, and the digital control circuit 60 may be implemented using any of a wide variety of circuit implementations and circuit techniques. Therefore, the description of each circuit provided below is exemplary and should not be so limited.

### [1.2.1 Circuit Configuration of Switched-Capacitor Circuit 20]

First, the circuit configuration of the switched-capacitor circuit 20 will be described. The switched-capacitor circuit 20 is connected to the digital control circuit 60. As shown in FIG. 3, the switched-capacitor circuit 20 includes regulated voltage input terminals 121, 122, 123, and 124, a control terminal 120, capacitors C11 to C16, capacitors C10, C20, C30, and C40, and switches S11 to S14, S21 to S24, S31 to S34, and S41 to S44. Energy and electric charges are inputted to the switched-capacitor circuit 20 from the regulated voltage input terminals 121 to 124, and extracted from the switched-capacitor circuit 20 to the supply modulator 30 at nodes N1 to N4.

The regulated voltage input terminal 121 is an external connection terminal that receives the regulated voltage outputted from an output terminal 111 of the pre-regulator circuit 310. The regulated voltage input terminal 122 is an external connection terminal that receives the regulated voltage outputted from an output terminal 112 of the pre-regulator circuit 310. The regulated voltage input terminal 123 is an external connection terminal that receives the regulated voltage outputted from an output terminal 113 of the pre-regulator circuit 310. The regulated voltage input terminal 124 is an external connection terminal that receives the regulated voltage outputted from an output terminal 114 of the pre-regulator circuit 310.

The control terminal 120 is an input terminal for a control signal S2. In other words, the control terminal 120 is a terminal for receiving the control signal S2 for controlling the switched-capacitor circuit 20.

In an exemplary aspect, each of the capacitors C11 to C16 can be configured a as a flying capacitor (sometimes called a “transfer capacitor”). In other words, each of the capacitors C11 to C16 is used to raise or lower the regulated voltage supplied from the pre-regulator circuit 310. More specifically, the capacitors C11 to C16 transfer electric charges between the capacitors C11 to C16 and the nodes N1 to N4 such that voltages V1 to V4 (voltages relative to the ground potential) satisfying V1:V2:V3:V4=1:2:3:4 are maintained at the four nodes N1 to N4. The voltages V1 to V4 correspond to the plurality of discrete voltages each having a respective one of the plurality of discrete voltage levels.

The capacitor C11 has two electrodes. One of the two electrodes of the capacitor C11 is connected to one end of the switch S11 and one end of the switch S12. The other of the two electrodes of the capacitor C11 is connected to one end of the switch S21 and one end of the switch S22.

The capacitor C12 has two electrodes. One of the two electrodes of the capacitor C12 is connected to one end of the switch S21 and one end of the switch S22. The other of the two electrodes of the capacitor C12 is connected to one end of the switch S31 and one end of the switch S32.

The capacitor C13 has two electrodes. One of the two electrodes of the capacitor C13 is connected to one end of the switch S31 and one end of the switch S32. The other of the two electrodes of the capacitor C13 is connected to one end of the switch S41 and one end of the switch S42.

The capacitor C14 has two electrodes. One of the two electrodes of the capacitor C14 is connected to one end of the switch S13 and one end of the switch S14. The other of the two electrodes of the capacitor C14 is connected to one end of the switch S23 and one end of the switch S24.

The capacitor C15 has two electrodes. One of the two electrodes of the capacitor C15 is connected to one end of the switch S23 and one end of the switch S24. The other of the two electrodes of the capacitor C15 is connected to one end of the switch S33 and one end of the switch S34.

The capacitor C16 has two electrodes. One of the two electrodes of the capacitor C16 is connected to one end of the switch S33 and one end of the switch S34. The other of the two electrodes of the capacitor C16 is connected to one end of the switch S43 and one end of the switch S44.

Each of the set of capacitors C11 and C14, the set of capacitors C12 and C15, and the set of capacitors C13 and C16 can be charged and discharged in a complementary manner by repeating a first phase and a second phase.

Specifically, in the first phase, the switches S12, S13, S22, S23, S32, S33, S42, and S43 are turned ON. Thus, for example, one of the two electrodes of the capacitor C12 is connected to the node N3, the other of the two electrodes of the capacitor C12 and one of the two electrodes of the capacitor C15 are connected to the node N2, and the other of the two electrodes of the capacitor C15 is connected to the node N1.

On the other hand, in the second phase, the switches S11, S14, S21, S24, S31, S34, S41, and S44 are turned ON. Thus, for example, one of the two electrodes of the capacitor C15 is connected to the node N3, the other of the two electrodes of the capacitor C15 and one of the two electrodes of the capacitor C12 are connected to the node N2, and the other of the two electrodes of the capacitor C12 is connected to the node N1.

By repeating the first phase and the second phase, for example, when one of the capacitors C12 and C15 is charged from the node N2, the other of the capacitors C12 and C15 can be discharged to the capacitor C30. In other words, the capacitors C12 and C15 can be charged and discharged in a complementary manner.

As with the set of capacitors C12 and C15, each of the set of capacitors C11 and C14 and the set of capacitors C13 and C16 can be charged and discharged in a complementary manner by repeating the first phase and the second phase.

Each of the capacitors C10, C20, C30, and C40 may be configured to function as a smoothing capacitor. In other words, the capacitors C10, C20, C30, and C40 are used for holding and smoothing the voltages V1 to V4 at the nodes N1 to N4 in this aspect.

The capacitor C10 is connected between the node N1 and the ground. Specifically, one of the two electrodes of the capacitor C10 is connected to the node N1. On the other hand, the other of the two electrodes of the capacitor C10 is connected to the ground.

The capacitor C20 is connected between the nodes N2 and N1. Specifically, one of the two electrodes of the capacitor C20 is connected to the node N2. On the other hand, the other of the two electrodes of the capacitor C20 is connected to the node N1.

The capacitor C30 is connected between the nodes N3 and N2. Specifically, one of the two electrodes of the capacitor C30 is connected to the node N3. On the other hand, the other of the two electrodes of the capacitor C30 is connected to the node N2.

The capacitor C40 is connected between the nodes N4 and N3. Specifically, one of the two electrodes of the capacitor C40 is connected to the node N4. On the other hand, the other of the two electrodes of the capacitor C40 is connected to the node N3.

The switch S11 is connected between one of the two electrodes of the capacitor C11 and the node N3. Specifically, one end of the switch S11 is connected to one of the two electrodes of the capacitor C11. On the other hand, the other end of the switch S11 is connected to the node N3.

The switch S12 is connected between one of the two electrodes of the capacitor C11 and the node N4. Specifically, one end of the switch S12 is connected to one of the two electrodes of the capacitor C11. On the other hand, the other end of the switch S12 is connected to the node N4.

The switch S21 is connected between one of the two electrodes of the capacitor C12 and the node N2. Specifically, one end of the switch S21 is connected to one of the two electrodes of the capacitor C12 and the other of the two electrodes of the capacitor C11. On the other hand, the other end of the switch S21 is connected to the node N2.

The switch S22 is connected between one of the two electrodes of the capacitor C12 and the node N3. Specifically, one end of the switch S22 is connected to one of the two electrodes of the capacitor C12 and the other of the two electrodes of the capacitor C11. On the other hand, the other end of the switch S22 is connected to the node N3.

The switch S31 is connected between the other of the two electrodes of the capacitor C12 and the node N1. Specifically, one end of the switch S31 is connected to the other of the two electrodes of the capacitor C12 and one of the two electrodes of the capacitor C13. On the other hand, the other end of the switch S31 is connected to the node N1.

The switch S32 is connected between the other of the two electrodes of the capacitor C12 and the node N2. Specifically, one end of the switch S32 is connected to the other of the two electrodes of the capacitor C12 and one of the two electrodes of the capacitor C13. On the other hand, the other end of the switch S32 is connected to the node N2. In other words, the other end of the switch S32 is connected to the other end of the switch S21.

The switch S41 is connected between the other of the two electrodes of the capacitor C13 and the ground. Specifically, one end of the switch S41 is connected to the other of the two electrodes of the capacitor C13. On the other hand, the other end of the switch S41 is connected to the ground.

The switch S42 is connected between the other of the two electrodes of the capacitor C13 and the node N1. Specifically, one end of the switch S42 is connected to the other of the two electrodes of the capacitor C13. On the other hand, the other end of the switch S42 is connected to the node N1. In other words, the other end of the switch S42 is connected to the other end of the switch S31.

The switch S13 is connected between one of the two electrodes of the capacitor C14 and the node N3. Specifically, one end of the switch S13 is connected to one of the two electrodes of the capacitor C14. On the other hand, the other end of the switch S13 is connected to the node N3. In other words, the other end of the switch S13 is connected to the other end of the switch S11 and the other end of the switch S22.

The switch S14 is connected between one of the two electrodes of the capacitor C14 and the node N4. Specifically, one end of the switch S14 is connected to one of the two electrodes of the capacitor C14. On the other hand, the other end of the switch S14 is connected to the node N4. In other words, the other end of the switch S14 is connected to the other end of the switch S12.

The switch S23 is connected between one of the two electrodes of the capacitor C15 and the node N2. Specifically, one end of the switch S23 is connected to one of the two electrodes of the capacitor C15 and the other of the two electrodes of the capacitor C14. On the other hand, the other end of the switch S23 is connected to the node N2. In other words, the other end of the switch S23 is connected to the other end of the switch S21 and the other end of the switch S32.

The switch S24 is connected between one of the two electrodes of the capacitor C15 and the node N3. Specifically, one end of the switch S24 is connected to one of the two electrodes of the capacitor C15 and the other of the two electrodes of the capacitor C14. On the other hand, the other end of the switch S24 is connected to the node N3. In other words, the other end of the switch S24 is connected to the other end of the switch S11, the other end of the switch S22, and the other end of the switch S13.

The switch S33 is connected between the other of the two electrodes of the capacitor C15 and the node N1. Specifically, one end of the switch S33 is connected to the other of the two electrodes of the capacitor C15 and one of the two electrodes of the capacitor C16. On the other hand, the other end of the switch S33 is connected to the node N1. In other words, the other end of the switch S33 is connected to the other end of the switch S31 and the other end of the switch S42.

The switch S34 is connected between the other of the two electrodes of the capacitor C15 and the node N2. Specifically, one end of the switch S34 is connected to the other of the two electrodes of the capacitor C15 and one of the two electrodes of the capacitor C16. On the other hand, the other end of the switch S34 is connected to the node N2. In other words, the other end of the switch S34 is connected to the other end of the switch S21, the other end of the switch S32, and the other end of the switch S23.

The switch S43 is connected between the other of the two electrodes of the capacitor C16 and the ground. Specifically, one end of the switch S43 is connected to the other of the two electrodes of the capacitor C16. On the other hand, the other end of the switch S43 is connected to the ground.

The switch S44 is connected between the other of the two electrodes of the capacitor C16 and the node N1. Specifically, one end of the switch S44 is connected to the other of the two electrodes of the capacitor C16. On the other hand, the other end of the switch S44 is connected to the node N1. In other words, the other end of the switch S44 is connected to the other end of the switch S31, the other end of the switch S42, and the other end of the switch S33.

A first set of switches including the switches S12, S13, S22, S23, S32, S33, S42, and S43 and a second set of switches including the switches S11, S14, S21, S24, S31, S34, S41, and S44 are switched ON and OFF in a complementary manner based on the control signal S2. Specifically, in the first phase, the first set of switches is turned ON and the second set of switches is turned OFF. Conversely, in the second phase, the first set of switches is turned OFF and the second set of switches is turned ON.

For example, the capacitors C10 to C40 are charged from the capacitors C11 to C13 in one of the first phase and second phase, and the capacitors C10 to C40 are charged from the capacitors C14 to C16 in the other of the first phase and second phase. In other words, since the capacitors C10 to C40 are always charged from the capacitors C11 to C13 or the capacitors C14 to C16, even if currents flow from the nodes N1 to N4 to the supply modulator 30 at a high speed, electric charges are replenished to the nodes N1 to N4 at high speed, so that the potential fluctuation of the nodes N1 to N4 can be suppressed.

Due to such an operation, the switched-capacitor circuit 20 can maintain substantially equal voltages at both ends of each of the capacitors C10, C20, C30, and C40. Specifically, the voltages V1 to V4 (voltages relative to the ground potential) satisfying V1:V2:V3:V4=1:2:3:4 are maintained at the four nodes labeled V1 to V4. The voltage levels of the voltages V1 to V4 correspond to the plurality of discrete voltage levels that can be supplied to the supply modulator 30 by the switched-capacitor circuit 20.

It is noted that the voltage ratio (V1:V2:V3:V4) is not limited to (1:2:3:4). For example, the voltage ratio (V1:V2:V3:V4) may be (1:2:4:8) in an alternative aspect.

The configuration of the switched-capacitor circuit 20 shown in FIG. 3 is an example, and is not limited to such an example. In FIG. 3, the switched-capacitor circuit 20 is configured to supply voltages of four discrete voltage levels, but the configuration of the switched-capacitor circuit 20 is not limited to that shown in FIG. 3. The switched-capacitor circuit 20 may be configured to supply voltages of any number of discrete voltage levels that is greater than or equal to two. For example, when supplying voltages of two discrete voltage levels, the switched-capacitor circuit 20 need only include at least the capacitors C12 and C15 and the switches S21 to S24 and S31 to S34.

### [1.2.2 Circuit Configuration of Supply Modulator 30]

Next, the circuit configuration of the supply modulator 30 will be described. The supply modulator 30 is connected to the digital control circuit 60. As shown in FIG. 3, the supply modulator 30 includes input terminals 131 to 134, a control terminal 135, switches S51 to S54, and an output terminal 130.

The output terminal 130 is connected to an external connection terminal 141. The output terminal 130 is a terminal for supplying a power supply voltage selected from the voltages V1 to V4 to the power amplifier 81 via the external connection terminal 141.

The input terminals 131 to 134 are connected to the nodes N4 to N1 of the switched-capacitor circuit 20, respectively. The input terminals 131 to 134 are terminals for receiving the voltages V4 to V1 from the switched-capacitor circuit 20.

The control terminal 135 is an input terminal for a control signal S3. In other words, the control terminal 135 is a terminal for receiving the control signal S3 that indicates one of the voltages V1 to V4. The supply modulator 30 controls ON and OFF of the switches S51 to S54 so as to select the voltage level indicated by the control signal S3.

The switch S51 is connected between the input terminal 131 and the output terminal 130. Specifically, the switch S51 has a terminal connected to the input terminal 131 and a terminal connected to the output terminal 130. In such a connection configuration, the switch S51 can switch between connection and disconnection of the input terminal 131 to and from the output terminal 130 by being switched ON and OFF by the control signal S3.

The switch S52 is connected between the input terminal 132 and the output terminal 130. Specifically, the switch S52 has a terminal connected to the input terminal 132 and a terminal connected to the output terminal 130. In such a connection configuration, the switch S52 can switch between connection and disconnection of the input terminal 132 to and from the output terminal 130 by being switched ON and OFF by the control signal S3.

The switch S53 is connected between the input terminal 133 and the output terminal 130. Specifically, the switch S53 has a terminal connected to the input terminal 133 and a terminal connected to the output terminal 130. In such a connection configuration, the switch S53 can switch between connection and disconnection of the input terminal 133 to and from the output terminal 130 by being switched ON and OFF by the control signal S3.

The switch S54 is connected between the input terminal 134 and the output terminal 130. Specifically, the switch S54 has a terminal connected to the input terminal 134 and a terminal connected to the output terminal 130. In such a connection configuration, the switch S54 can switch between connection and disconnection of the input terminal 134 to and from the output terminal 130 by being switched ON and OFF by the control signal S3.

The switches S51 to S54 are controlled to be exclusively ON. In other words, only one of the switches S51 to S54 is turned ON, and the rest of the switches S51 to S54 are turned OFF. With such a configuration, the supply modulator 30 can output one voltage selected from the voltages V1 to V4.

Note that the configuration of the supply modulator 30 shown in FIG. 3 is an example, and is not limited to such an example. In particular, the switches S51 to S54 may have any configuration as long as at least one of the four input terminals 131 to 134 can be selectively connected to the output terminal 130. For example, the supply modulator 30 may further include a switch connected between the switches S51 to S53 and both the switch S54 and the output terminal 130. Also, for example, the supply modulator 30 may further include a switch connected between the switches S51 and S52 and both the switches S53 and S54 and the output terminal 130.

In an exemplary aspect, when voltages of two discrete voltage levels are supplied from the switched-capacitor circuit 20, the supply modulator 30 need only include at least two of the switches S51 to S54.

### [1.2.3 Circuit Configuration of Pre-Regulator Circuit 310]

First, the configuration of the pre-regulator circuit 310 will be described. As shown in FIG. 3, the pre-regulator circuit 310 includes an input terminal 110, the output terminals 111 to 114, a control terminal 117, inductor connection terminals 115 and 116, switches S61 to S63, S71, and S72, a power inductor L71, and capacitors C61 to C64.

The input terminal 110 is an input terminal for a DC voltage. In other words, the input terminal 110 is a terminal for receiving an input voltage from the DC power source 350.

The output terminal 111 is an output terminal for the voltage V4. In other words, the output terminal 111 is a terminal for supplying the voltage V4 to the switched-capacitor circuit 20. The output terminal 111 is connected to the node N4 of the switched-capacitor circuit 20 via the regulated voltage input terminal 121.

The output terminal 112 is an output terminal for the voltage V3. In other words, the output terminal 112 is a terminal for supplying the voltage V3 to the switched-capacitor circuit 20. The output terminal 112 is connected to the node N3 of the switched-capacitor circuit 20 via the regulated voltage input terminal 122.

The output terminal 113 is an output terminal for the voltage V2. In other words, the output terminal 113 is a terminal for supplying the voltage V2 to the switched-capacitor circuit 20. The output terminal 113 is connected to the node N2 of the switched-capacitor circuit 20 via the regulated voltage input terminal 123.

The output terminal 114 is an output terminal for the voltage V1. In other words, the output terminal 114 is a terminal for supplying the voltage V1 to the switched-capacitor circuit 20. The output terminal 114 is connected to the node N1 of the switched-capacitor circuit 20 via the regulated voltage input terminal 124.

The inductor connection terminal 115 is connected to one end of the power inductor L71. The inductor connection terminal 116 is connected to the other end of the power inductor L71.

The control terminal 117 is an input terminal for a control signal S1. In other words, the control terminal 117 is a terminal for receiving the control signal S1 for controlling the pre-regulator circuit 310.

The switch S71 is connected between the input terminal 110 and one end of the power inductor L71. Specifically, the switch S71 has a terminal connected to the input terminal 110 and a terminal connected to one end of the power inductor L71 via the inductor connection terminal 115. In such a connection configuration, the switch S71 can switch between connection and disconnection of the input terminal 110 to and from one end of the power inductor L71 by being switched ON and OFF based on the control signal S1.

The switch S72 is connected between one end of the power inductor L71 and the ground. Specifically, the switch S72 has a terminal connected to one end of the power inductor L71 via the inductor connection terminal 115 and a terminal connected to the ground. In such a connection configuration, the switch S72 can switch between connection and disconnection of one end of the power inductor L71 to and from the ground by being switched ON and OFF based on the control signal S1.

The switch S61 is connected between the other end of the power inductor L71 and the output terminal 111. Specifically, the switch S61 has a terminal connected to the other end of the power inductor L71 via the inductor connection terminal 116 and a terminal connected to the output terminal 111. In such a connection configuration, the switch S61 can switch between connection and disconnection of the other end of the power inductor L71 to and from the output terminal 111 by being switched ON and OFF based on the control signal S1.

The switch S62 is connected between the other end of the power inductor L71 and the output terminal 112. Specifically, the switch S62 has a terminal connected to the other end of the power inductor L71 via the inductor connection terminal 116 and a terminal connected to the output terminal 112. In such a connection configuration, the switch S62 can switch between connection and disconnection of the other end of the power inductor L71 to and from the output terminal 112 by being switched ON and OFF based on the control signal S1.

The switch S63 is connected between the other end of the power inductor L71 and the output terminal 113. Specifically, the switch S63 has a terminal connected to the other end of the power inductor L71 via the inductor connection terminal 116 and a terminal connected to the output terminal 113. In such a connection configuration, the switch S63 can switch between connection and disconnection of the other end of the power inductor L71 to and from the output terminal 113 by being switched ON and OFF based on the control signal S1.

One of the two electrodes of the capacitor C61 is connected to the switch S61 and the output terminal 111. The other of the two electrodes of the capacitor C61 is connected to the switch S62, the output terminal 112, and one of the two electrodes of the capacitor C62.

One of the two electrodes of the capacitor C62 is connected to the switch S62, the output terminal 112, and the other of the two electrodes of the capacitor C61. The other of the two electrodes of the capacitor C62 is connected to the switch S63, the output terminal 113, and one of the two electrodes of the capacitor C63.

One of the two electrodes of the capacitor C63 is connected to the switch S63, the output terminal 113, and the other of the two electrodes of the capacitor C62. The other of the two electrodes of the capacitor C63 is connected to the output terminal 114 and one of the two electrodes of the capacitor C64.

One of the two electrodes of the capacitor C64 is connected to the output terminal 114 and the other of the two electrodes of the capacitor C63. The other of the two electrodes of the capacitor C64 is connected to the ground.

The switches S61 to S63 are controlled to be exclusively ON. In other words, only one of the switches S61 to S63 is turned ON, and the rest of the switches S61 to S63 are turned OFF. By turning ON only one of the switches S61 to S63, the pre-regulator circuit 310 can change the voltage supplied to the switched-capacitor circuit 20 at the voltage levels of the voltages V2 to V4.

The pre-regulator circuit 310 thus configured can supply a regulated voltage to the switched-capacitor circuit 20 via at least one of the output terminals 111 to 113.

In an exemplary aspect, when the input voltage is to be converted into one single regulated voltage, the pre-regulator circuit 310 need only include at least the switches S71 and S72 and the power inductor L71.

### [1.2.4 Circuit Configuration of Filter Circuit 40]

Next, the circuit configuration of the filter circuit 40 will be described. As shown in FIG. 3, the filter circuit 40 includes inductors L51, L52, and L53, capacitors C51 and C52, a resistor R51, an input terminal 140, and the external connection terminal (output terminal) 141.

The input terminal 140 is an input terminal for the discrete voltage selected by the supply modulator 30. In other words, the input terminal 140 is a terminal for receiving the discrete voltage selected from the plurality of voltages V1 to V4.

The external connection terminal 141 is an output terminal for the power supply voltage V_{T1}. In other words, the external connection terminal 141 is a terminal for supplying the power supply voltage V_{T1} to the amplifier circuit 2.

The inductor L51 and the inductor L52 are connected in series with each other between the input terminal 140 and the external connection terminal 141. The series connection circuit of the inductor L53 and the resistor R51 is connected in parallel with the inductor L51. The capacitor C51 is connected between the connection point of the inductors L51 and L52 and the ground. The capacitor C52 is connected between the external connection terminal 141 and the ground.

In the above configuration, the filter circuit 40 forms an LC low pass filter in which the inductors are arranged in a series arm path and the capacitors are arranged in parallel arm paths. With such a configuration, the filter circuit 40 can reduce radio frequency components included in the power supply voltage. For example, when a predetermined band is a frequency band for frequency division duplex (FDD), the filter circuit 40 is configured to reduce components of the downlink operating band of the predetermined band.

Note that the configuration of the filter circuit 40 shown in FIG. 3 is an example, and is not limited to such an example. The filter circuit 40 may be configured as a band pass filter or a high pass filter, depending on the band to be removed.

The filter circuit 40 may also include two or more LC filters. It is sufficient that the two or more LC filters are commonly connected to the output terminal 130, and each LC filter has a pass band or attenuation band corresponding to a respective one of different bands. Alternatively, a first filter group composed of two or more LC filters may be connected to a first output terminal of the supply modulator 30, a second filter group composed of two or more other LC filters may be connected to a second output terminal of the supply modulator 30, and each LC filter may have a pass band or attenuation band corresponding to a respective one of different bands. In such a case, the filter circuit 40 may have two or more output terminals, and may simultaneously output two or more power supply voltages V_{T1} to the amplifier circuit 2.

### [1.2.5 Circuit Configuration of Digital Control Circuit 60]

Next, the circuit configuration of the digital control circuit 60 will be described. As shown in FIG. 4, the digital control circuit 60 includes a first controller 61, a second controller 62, and control terminals 601 to 604.

The first controller 61 can process a source-synchronous digital control signal received from the RFIC 3 via the control terminals 601 and 602 to generate the control signal S2. The control signal S2 is a signal for controlling ON and OFF of the switches S11 to S14, S21 to S24, S31 to S34, and S41 to S44 included in the switched-capacitor circuit 20.

Note that the digital control signal to be processed by the first controller 61 is not limited to the source-synchronous digital control signal. For example, the first controller 61 may process a clock-embedded digital control signal. The first controller 61 may also generate a control signal for controlling the supply modulator 30.

The second controller 62 processes digitally controlled level (DCL: digital control logic/line) signals (DCL1 and DCL2) received from the RFIC 3 via the control terminals 603 and 604 to generate the control signal S3. The DCL signals (DCL1 and DCL2) are generated by the RFIC 3 based on an envelope signal of a radio frequency signal or the like. The control signal S3 is a signal for controlling ON and OFF of the switches S51 to S54 included in the supply modulator 30.

Each of the DCL signals (DCL1 and DCL2) is a 1-bit signal. Each of the voltages V1 to V4 is represented by a combination of two 1-bit signals. For example, V1, V2, V3, and V4 are represented by “00”, “01”, “10”, and “11”, respectively. A gray code may be used to express the voltage level in an exemplary aspect.

Note that, in the present embodiment, two digitally controlled level signals are used to control the supply modulator 30, but the number of digitally controlled level signals is not limited to two. For example, one digitally controlled level signal or any number of digitally controlled level signals that is greater than or equal to three may be used, depending on the number of voltage levels of the supply modulator 30 that are each selectable. Further, the digital control signal used to control the supply modulator 30 is not limited to the digitally controlled level signals.

For purposes of this disclosure, in the communication device 6 described above, when the switched-capacitor circuit 20 generates a plurality of discrete voltages having different voltage levels based on the regulated voltage outputted from the pre-regulator circuit 310, it is assumed that the voltage output characteristics of the tracker circuit 1 will deteriorate due to the heat generated by the pre-regulator circuit 310 and the switched-capacitor circuit 20, and the efficiency (PAE: power added efficiency) of the amplifier circuit 2 will deteriorate.

The configuration of a tracker module for suppressing the efficiency deterioration of the amplifier circuit 2 according to the present embodiment will be described below.

### [1.3 Implementation Configuration of Tracker Module 7]

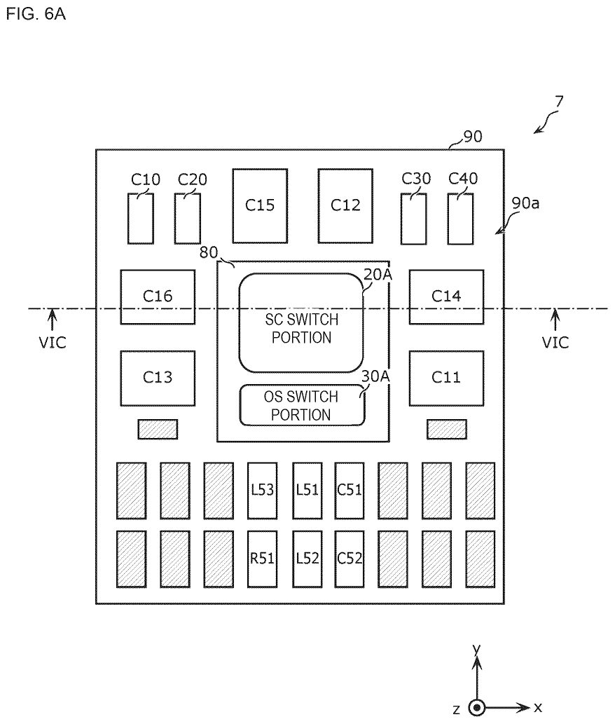

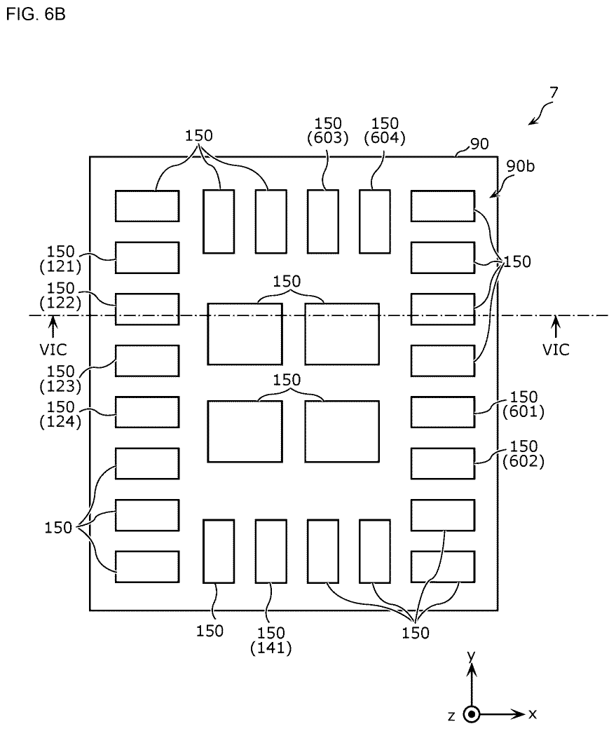

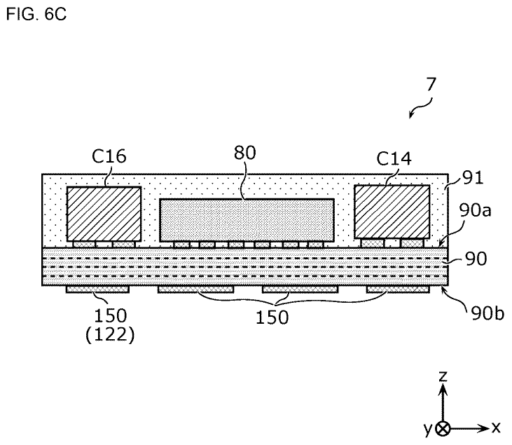

Next, the configuration of a tracker module 7 and its peripheral circuits as an implementation example of the tracker circuit 1 configured as described above will be described with reference to FIGS. 5 to 6C.

FIG. 5 is a configuration diagram of the tracker module 7 and its peripheral circuits according to the exemplary embodiment. As shown in FIG. 5, the tracker module 7 includes a module laminate 90, the switched-capacitor circuit 20, the supply modulator 30, the filter circuit 40, the regulated voltage input terminals 121, 122, 123, and 124, the control terminals 601 to 604, and the external connection terminal 141.

The module laminate 90 is a substrate that separate from a substrate 390. In this aspect, the pre-regulator circuit 310 is disposed on the substrate 390. Moreover, the switched-capacitor circuit 20, the supply modulator 30, and the filter circuit 40 are disposed on the module laminate 90.

In the present embodiment, all circuit components included in the switched-capacitor circuit 20, the supply modulator 30, and the filter circuit 40 are disposed on the module laminate 90. For purposes of this disclosure, the circuit components are defined as those including active elements such as transistors and diodes, and passive elements such as resistors, coils, and capacitors, but not including wiring lines, electrodes, or terminals.

Each of the regulated voltage input terminals 121 to 124 is an example of a first regulated voltage input terminal, and is an externally connectable terminal that receives the first regulated voltage.

The pre-regulator circuit 310 is an example of a first converter, and is configured to convert the input voltage into the first regulated voltage.

The switched-capacitor circuit 20 is configured to generate a plurality of discrete voltages based on the first regulated voltage.

The supply modulator 30 is configured to selectively output at least one of the plurality of discrete voltages to the amplifier circuit 2.

With the configuration described above, since the circuit components of the pre-regulator circuit 310 and the circuit components of the switched-capacitor circuit 20 and the supply modulator 30 are disposed on different substrates, the tracker module 7 including the switched-capacitor circuit 20 and the supply modulator 30 but not including the pre-regulator circuit 310 is not susceptible to the heat generated by the pre-regulator circuit 310. With such a configuration, since the heat generated by the tracker module 7 can be suppressed, the deterioration of the voltage output characteristics of the switched-capacitor circuit 20 and the supply modulator 30 can be suppressed. Therefore, the efficiency deterioration of the amplifier circuit 2 that receives the power supply voltage from the tracker module 7 can be suppressed.

Note that it is sufficient that at least the switches and capacitors included in the switched-capacitor circuit 20 and the switches included in the supply modulator 30 are disposed on the module laminate 90. Further, it is sufficient that the switches included in the pre-regulator circuit 310 are disposed on the substrate 390.

Each of the regulated voltage input terminals 121 to 124 is an example of the first regulated voltage input terminal, and is an externally connectable terminal that receives the first regulated voltage.

With the regulated voltage input terminals 121 to 124, since the first regulated voltage generated by the pre-regulator circuit 310 is supplied from the outside of the tracker module 7, the tracker module 7 including the switched-capacitor circuit 20 and the supply modulator 30 but not including the pre-regulator circuit 310 is not susceptible to the heat generated by the pre-regulator circuit 310. With such a configuration, since the heat generated by the tracker module 7 can be suppressed, the deterioration of the voltage output characteristics of the switched-capacitor circuit 20 and the supply modulator 30 can be suppressed. Therefore, the efficiency deterioration of the amplifier circuit 2 that receives the power supply voltage from the tracker module 7 can be suppressed.

The control terminals 601 and 602 are externally connectable digital control terminals that receive the source-synchronous digital control signal. The control terminals 603 and 604 are externally connectable digital control terminals that receive the DCL signals.

FIG. 6A is a plan view of the tracker module 7 according to the exemplary embodiment, and is obtained when a main surface 90a side of the module laminate 90 is viewed from the positive direction of the z-axis. FIG. 6B is a plan view of the tracker module 7 according to the exemplary embodiment, and is obtained when a main surface 90b side of the module laminate 90 is viewed, in a transparent manner, from the positive direction of the z-axis. FIG. 6C is a cross-sectional view of the tracker module 7 according to the exemplary embodiment, and more specifically, is a cross-sectional view taken along line VIC-VIC of FIGS. 6A and 6B.

As shown in FIGS. 6A to 6C, the tracker module 7 according to the present embodiment includes the module laminate 90, an integrated circuit 80, the capacitors C10, C20, C30, C40, C11, C12, C13, C14, C15, C16, C51, and C52, the inductors L51, L52, and L53, the resistor R51, external connection electrodes 150, and a resin member 91.

The module laminate 90 has a main surface 90a and a main surface 90b facing each other, and is a substrate on which the circuit components forming the tracker module 7 are mounted. For example, a substrate having a multilayer structure including a plurality of dielectric layers, such as an LTCC (low temperature co-fired ceramic) substrate, an HTCC (high temperature co-fired ceramic) substrate, a component-embedded board, a substrate having an RDL (redistribution layer), a printed circuit board, or the like, is used as the module laminate 90.

The integrated circuit 80 is an example of a first semiconductor IC (integrated circuit); the integrated circuit 80 is formed by using, for example, a CMOS (complementary metal oxide semiconductor), and is specifically manufactured by an SOI (silicon on insulator) process. The integrated circuit 80 may be formed of at least one of GaAs, SiGe, and GaN. Note that the semiconductor material of the integrated circuit 80 is not limited to the above-mentioned materials.

The integrated circuit 80 has an SC switch portion 20A and an OS switch portion 30A.

The SC switch portion 20A is composed of the switches included in the switched-capacitor circuit 20. Specifically, the SC switch portion 20A includes the switches S11, S12, S13, S14, S21, S22, S23, S24, S31, S32, S33, S34, S41, S42, S43, and S44.

The OS switch portion 30A is composed of the switches included in the supply modulator 30. Specifically, the OS switch portion 30A includes the switches S51, S52, S53, and S54.

The capacitors C10, C20, C30, C40, C11, C12, C13, C14, C15, and C16 are the capacitors included in the switched-capacitor circuit 20. The capacitors C51 and C52 are the capacitors included in the filter circuit 40.

It is noted that the digital control circuit 60 may be included in the integrated circuit 80 in an exemplary aspect.

With such a configuration, since the switches included in the switched-capacitor circuit 20 and the switches included in the supply modulator 30 are integrated by the integrated circuit 80, the size of the tracker module 7 can be reduced.

In an exemplary aspect, the resin member 91 is disposed on the main surface 90a and covers some of the circuit components forming the tracker module 7 and the main surface 90a. The resin member 91 has a function of ensuring reliability, such as mechanical strength and moisture resistance, of the circuit components forming the tracker module 7. Note that the resin member 91 may be considered an optional component of the tracker module 7 according to the present embodiment.

It should be appreciated that the integrated circuit 80 may not be a single integrated circuit, and may be composed of two integrated circuits, one having the SC switch portion 20A and the other having the OS switch portion 30A in an alternative aspect.

The external connection electrodes 150 are disposed on the main surface 90b. The tracker module 7 exchanges electric signals, via the plurality of external connection electrodes 150, with the RFIC 3, the amplifier circuit 2, the pre-regulator circuit 310, and a mother board disposed on the negative side of the z-axis. The regulated voltage input terminals 121 to 124, the control terminals 601 to 604, and the external connection terminal 141 are included in the external connection electrodes 150. Some of the plurality of external connection electrodes 150 are set to the ground potential.

The external connection electrodes 150 may be planar electrodes as shown in FIG. 6B, or bump electrodes formed on the main surface 90b according to various exemplary aspects.

Further, although not shown in FIGS. 6A to 6C, wiring lines connecting the circuit components are formed within the module laminate 90 and formed on the main surfaces 90a and 90b. The wiring lines may be bonding wires both ends of which are bonded to any of the main surfaces 90a and 90b and the circuit components, or may be terminals, electrodes, or wiring lines formed on the surface of the circuit components.

In the tracker module 7, the regulated voltage input terminals 121 to 124 are disposed on the main surface 90b. Further, the switches (the SC switch portion 20A) and the capacitors (the capacitors C10, C20, C30, C40, C11, C12, C13, C14, C15, and C16) included in the switched-capacitor circuit 20 and the switches (the OS switch portion 30A) included in the supply modulator 30 are disposed on the main surface 90a.

With such a configuration, since the regulated voltage input terminals 121 to 124, the switches and capacitors included in the switched-capacitor circuit 20, and the switches included in the supply modulator 30 are disposed on both sides of the module laminate 90, the size of the tracker module 7 can be reduced while also diffusing the heat generated by the tracker module 7.

In addition, when the module laminate 90 is viewed in plan view, the regulated voltage input terminals 121 to 124 overlap with at least some of the capacitors included in the switched-capacitor circuit 20. Specifically, as shown in FIGS. 6A and 6B, the regulated voltage input terminal 121 overlaps with the capacitor C10, the regulated voltage input terminal 122 overlaps with the capacitor C16, the regulated voltage input terminal 123 overlaps with the capacitor C13, and the regulated voltage input terminal 124 overlaps with the capacitor C13.

With such a configuration, since the wiring lines for transmitting the regulated voltage to the capacitors in the switched-capacitor circuit 20 can be shortened, the voltage output characteristics of the switched-capacitor circuit 20 can be improved.

Further, the regulated voltage input terminals 121 to 124 are disposed on the outermost peripheral portion of the main surface 90b.

With such a configuration, since the wiring lines that transmit the regulated voltage generated by the pre-regulator circuit 310 disposed outside the tracker module 7 to the regulated voltage input terminals 121 to 124 can be shortened, the transmission loss of the regulated voltage can be reduced.

According to an exemplary aspect, a state in which a terminal is disposed on the outermost peripheral portion of the main surface can mean that no circuit component is disposed between the outer edge of the main surface and the terminal.

Note that the configuration of the tracker module 7 shown in FIGS. 6A to 6C is an example and is not limited to such an example. For example, some of the capacitors, inductors, and resistor disposed on the main surface 90a may be formed in the module laminate 90 in an exemplary aspect.

### [1.4 Implementation Configuration of Tracker Module 7A According to Variation 1]

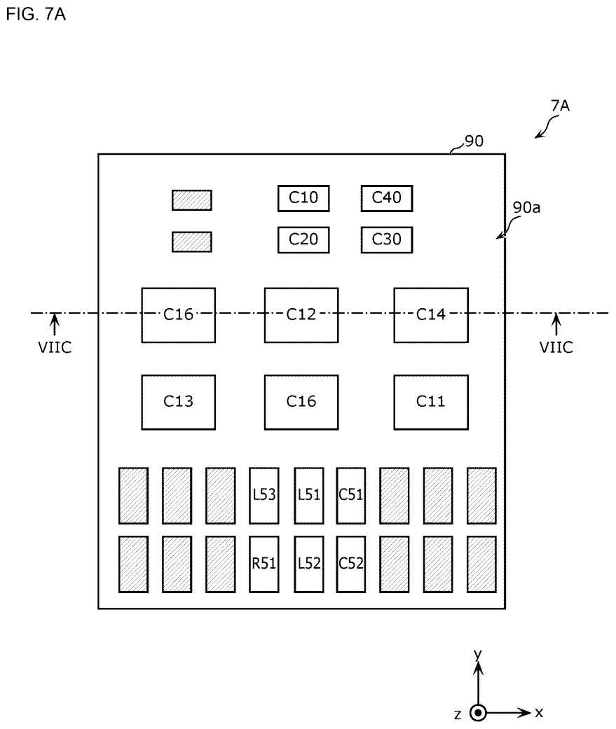

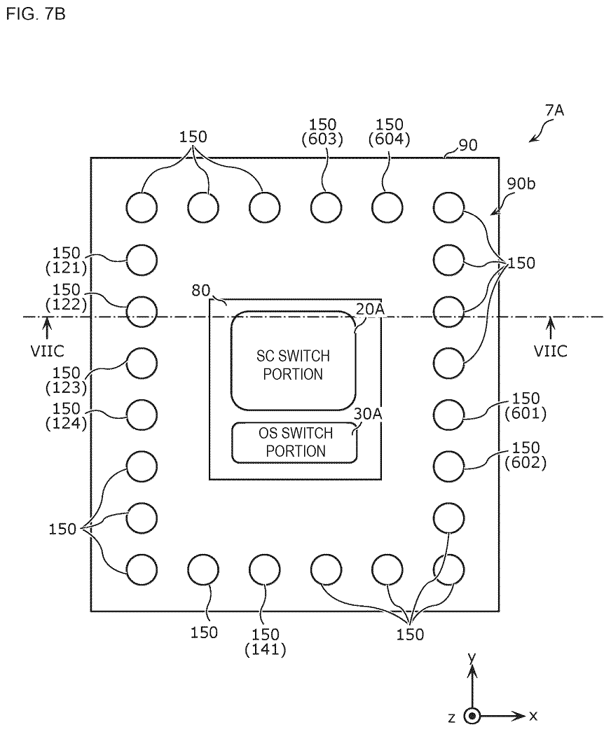

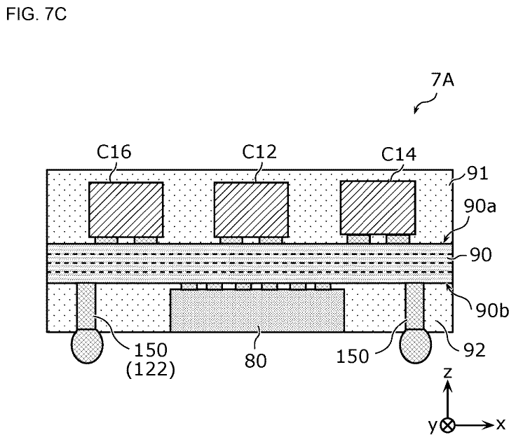

FIG. 7A is a plan view of a tracker module 7A according to Variation 1 of the exemplary embodiment and is obtained when a main surface 90a side of a module laminate 90 is viewed from the positive direction of the z-axis. FIG. 7B is a plan view of the tracker module 7A according to Variation 1 and is obtained when a main surface 90b side of the module laminate 90 is viewed, in a transparent manner, from the positive direction of the z-axis. FIG. 7C is a cross-sectional view of the tracker module 7A according to Variation 1, and more specifically, is a cross-sectional view taken along line VIIC-VIIC of FIGS. 7A and 7B.

As shown in FIGS. 7A to 7C, the tracker module 7A according to the present variation includes the module laminate 90, an integrated circuit 80, capacitors C10, C20, C30, C40, C11, C12, C13, C14, C15, C16, C51, and C52, inductors L51, L52, and L53, a resistor R51, external connection electrodes 150, and resin members 91 and 92. The tracker module 7A according to the present variation is different from the tracker module 7 according to the exemplary embodiment in the arrangement and configuration of the integrated circuit 80. Hereinafter, in the tracker module 7A according to the present variation, the same parts as those of the tracker module 7 according to the exemplary embodiment will be omitted, and only different parts will be mainly described.

The integrated circuit 80 has an SC switch portion 20A and an OS switch portion 30A.

In an exemplary aspect, the resin member 91 is disposed on the main surface 90a, covers some of the circuit components forming the tracker module 7A, and covers the main surface 90a. The resin member 92 is disposed on the main surface 90b, covers some of the circuit components forming the tracker module 7A, and covers the main surface 90b. The resin members 91 and 92 have functions of ensuring reliability, such as mechanical strength and moisture resistance, of the circuit components forming the tracker module 7A. It is noted that the resin members 91 and 92 may be optional components of the tracker module 7A according to the present variation.

The external connection electrodes 150 are disposed on the main surface 90b. Regulated voltage input terminals 121 to 124, control terminals 601 to 604, and an external connection terminal 141 are included in the external connection electrodes 150. Some of the plurality of external connection electrodes 150 are set to the ground potential.

The external connection electrodes 150 may be bump electrodes as shown in FIG. 7B, or planar electrodes formed on the main surface 90b according to various exemplary aspects.

In the tracker module 7A, the regulated voltage input terminals 121 to 124 and the integrated circuit 80 are disposed on the main surface 90b. The capacitors (the capacitors C10, C20, C30, C40, C11, C12, C13, C14, C15, and C16) included in a switched-capacitor circuit 20 are disposed on the main surface 90a.

With such a configuration, since the switches included in the switched-capacitor circuit 20, the switches included in a supply modulator 30 (the integrated circuit 80), and the capacitors included in the switched-capacitor circuit 20 are disposed on both sides of the module laminate 90, the size of the tracker module 7A can be reduced.

The regulated voltage input terminals 121 to 124 are disposed on the outermost peripheral portion of the main surface 90b.

With such a configuration, since the wiring lines that transmit the regulated voltage generated by a pre-regulator circuit 310 disposed outside the tracker module 7A to the regulated voltage input terminals 121 to 124 can be shortened, the transmission loss of the regulated voltage can be reduced.

Note that the configuration of the tracker module 7A shown in FIGS. 7A to 7C is an example and is not limited to such an example. For example, some of the capacitors, inductors, and resistor disposed on the main surface 90a may be formed in the module laminate 90, and some of the switches disposed on the main surface 90b may be formed outside the integrated circuit 80 in exemplary aspects.

### [1.5 Implementation Configuration of Tracker Module 7B According to Variation 2]

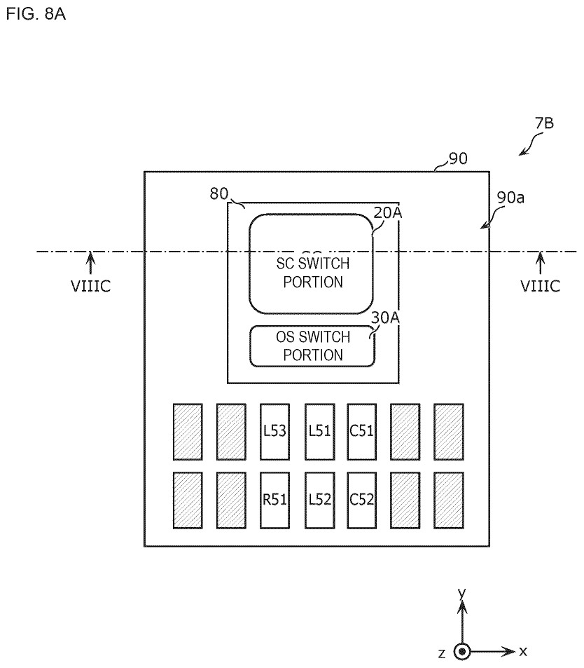

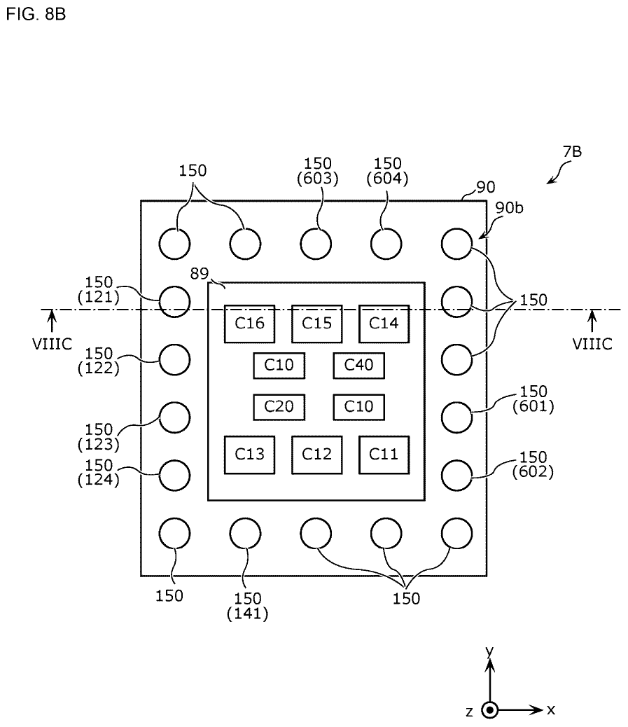

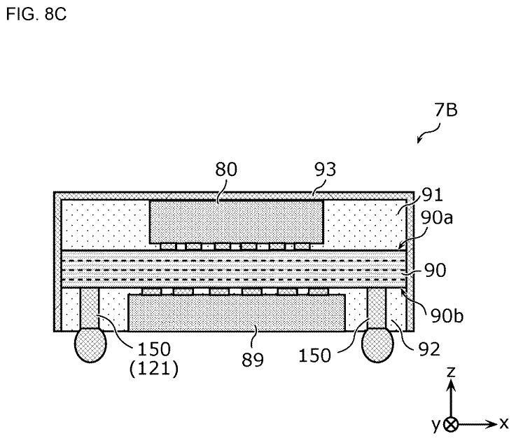

FIG. 8A is a plan view of a tracker module 7B according to Variation 2 of the exemplary embodiment and is obtained when a main surface 90a of a module laminate 90 is viewed from the positive direction of the z-axis. FIG. 8B is a plan view of the tracker module 7B according to Variation 2 and is obtained when a main surface 90b of the module laminate 90 is viewed, in a transparent manner, from the positive direction of the z-axis. FIG. 8C is a cross-sectional view of the tracker module 7B according to Variation 2, and more specifically, is a cross-sectional view taken along line VIIIC-VIIIC of FIGS. 8A and 8B.

As shown in FIGS. 8A to 8 C, the tracker module 7B according to the present variation includes the module laminate 90, integrated circuits 80 and 89, capacitors C51 and C52, inductors L51, L52, and L53, a resistor R51, external connection electrodes 150, resin members 91 and 92, and a shield electrode layer 93. The tracker module 7B according to the present variation is different from the tracker module 7A according to Variation 1 in the arrangement configuration of capacitors included in the integrated circuit 80 and the switched-capacitor circuit 20. Hereinafter, in the tracker module 7B according to the present variation, the same parts as those of the tracker module 7A according to Variation 1 will be omitted, and only different parts will be mainly described.

The integrated circuit 80 is an example of a second semiconductor IC. The integrated circuit 80 has an SC switch portion 20A and an OS switch portion 30A.

The SC switch portion 20A is composed of the switches included in a switched-capacitor circuit 20. Specifically, the SC switch portion 20A includes switches S11, S12, S13, S14, S21, S22, S23, S24, S31, S32, S33, S34, S41, S42, S43, and S44.

The OS switch portion 30A is composed of the switches included in a supply modulator 30. Specifically, the OS switch portion 30A includes switches S51, S52, S53, and S54.

The integrated circuit 89 is an example of an integrated passive device, and is formed, for example, by forming passive elements on a silicon substrate. The integrated circuit 89 includes capacitors C10, C20, C30, C40, C11, C12, C13, C14, C15, and C16 forming the switched-capacitor circuit 20.

The integrated circuit 80 is disposed on the main surface 90a, and the integrated circuit 89 is disposed on the main surface 90b.

With such a configuration, since the switches included in the switched-capacitor circuit 20 are integrated, and the integrated circuits 80 and 88 are disposed on both sides of the module laminate 90, the size of the tracker module 7B can be reduced.

Further, regulated voltage input terminals 121 to 124 are disposed on the outermost peripheral portion of the main surface 90b.

With such a configuration, since the wiring lines that transmit the regulated voltage generated by a pre-regulator circuit 310 disposed outside the tracker module 7B to the regulated voltage input terminals 121 to 124 can be shortened, the transmission loss of the regulated voltage can be reduced.

The shield electrode layer 93 covers at least a portion of the surface of the tracker module 7B and is connected to the ground. In the present variation, the shield electrode layer 93 is in contact with the integrated circuit 80, the resin members 91 and 92, and the module laminate 90. Specifically, among a third main surface and a fourth main surface facing each other of the integrated circuit 80, the third main surface faces the main surface 90a, and the fourth main surface faces the shield electrode layer 93. Among a fifth main surface and a sixth main surface facing each other of the integrated circuit 89, the fifth main surface faces the main surface 90b, and the sixth main surface is exposed.

With such a configuration, since the integrated circuit 89 has an IPD structure, the sixth main surface side can be polished, so that the integrated circuit 89 can be made thin. Further, the integrated circuit 80 can expose the fourth main surface from the resin member 91 by polishing the fourth main surface side, and the exposed fourth main surface can be brought into contact with the shield electrode layer 93. Therefore, the shielding property of the integrated circuit 80 is enhanced, the operating performance of each switch included in the integrated circuit 80 is improved, and the height of the tracker module 7B can be reduced.

Further, when the module laminate 90 is viewed in plan view, the regulated voltage input terminals 121 to 124 do not overlap with the integrated circuit 80.

With such a configuration, the heat flowing in via the regulated voltage input terminals 121 to 124 due to the regulated voltage generated by the pre-regulator circuit 310 can be suppressed from diffusing into the integrated circuit 80. Therefore, the operating performance of each switch included in the integrated circuit 80 is improved.

Note that the configuration of the tracker module 7B shown in FIGS. 8A to 8C is an example and is not limited to such an example. For example, some of the capacitors, inductors, and resistor disposed on the main surfaces 90a and 90b may be formed in the module laminate 90, and some of the switches disposed on the main surface 90a may be formed outside the integrated circuit 80.

### [1.6 Implementation Configuration of Tracker Module 7C According to Variation 3]

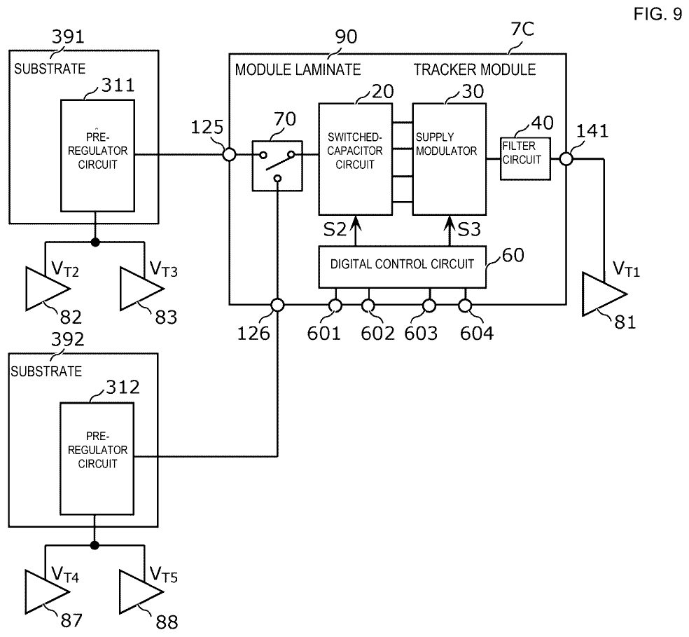

FIG. 9 is a circuit configuration diagram of a tracker module 7C and its peripheral circuits according to Variation 3 of the exemplary embodiment. As shown in FIG. 9, the tracker module 7C includes a module laminate 90, a switched-capacitor circuit 20, a supply modulator 30, a filter circuit 40, a switch 70, regulated voltage input terminals 125 and 126, control terminals 601 to 604, and an external connection terminal 141. The tracker module 7C according to the present variation differs from the tracker module 7 according to the exemplary embodiment in that the switch 70 is added and the configuration of the regulated voltage input terminals 125 and 126 is different. Hereinafter, in the tracker module 7C according to the present variation, the same parts as those of the tracker module 7 according to the exemplary embodiment will be omitted, and only different parts will be mainly described.

The module laminate 90 is a substrate separate from substrates 391 and 392. A pre-regulator circuit 311 is disposed on the substrate 391, and a pre-regulator circuit 312 is disposed on the substrate 392. The switched-capacitor circuit 20, the supply modulator 30, the filter circuit 40, and the switch 70 are disposed on the module laminate 90.

In the present variation, all circuit components included in the switched-capacitor circuit 20, the supply modulator 30, and the filter circuit 40 are disposed on the module laminate 90.

The regulated voltage input terminal 125 is an example of the first regulated voltage input terminal and is an externally connectable terminal that receives a first regulated voltage generated by the pre-regulator circuit 311. The regulated voltage input terminal 126 is an example of a second regulated voltage input terminal and is an externally connectable terminal that receives a second regulated voltage generated by the pre-regulator circuit 312.

The pre-regulator circuit 311 is an example of a first converter and is configured to convert the input voltage into the first regulated voltage. The pre-regulator circuit 312 is an example of a second converter and is configured to convert the input voltage into the second regulated voltage.

The switched-capacitor circuit 20 is configured to generate a plurality of discrete voltages based on the first regulated voltage or the second regulated voltage.

The supply modulator 30 is configured to selectively output at least one of the plurality of discrete voltages to an amplifier circuit 2.

The switch 70 is an example of a first switch and is disposed on the module laminate 90, and switches between connection of the regulated voltage input terminal 125 to the switched-capacitor circuit 20 and connection of the regulated voltage input terminal 126 to the switched-capacitor circuit 20. Specifically, the switch 70 has a common terminal, a first selection terminal, and a second selection terminal, and switches between connection of the common terminal to the first selection terminal and connection of the common terminal to the second selection terminal. The common terminal is connected to the switched-capacitor circuit 20, the first selection terminal is connected to the regulated voltage input terminal 125, and the second selection terminal is connected to the regulated voltage input terminal 126.

The external connection terminal 141 is connected to a power amplifier 81.

Power amplifiers 82 and 83 are connected to the pre-regulator circuit 311 without the tracker module 7C interposed therebetween, and power amplifiers 87 and 88 are connected to the pre-regulator circuit 312 without the tracker module 7C interposed therebetween.

In an exemplary aspect, the power amplifiers 81, 82, 83, 87, and 88 collectively form the amplifier circuit.

With the configuration described above, since the circuit components of the pre-regulator circuits 311 and 312 and the circuit components of the switched-capacitor circuit 20 and the supply modulator 30 are disposed on different substrates, the tracker module 7C including the switched-capacitor circuit 20 and the supply modulator 30 but not including the pre-regulator circuits 311 and 312 is not affected by the heat generated by the pre-regulator circuits 311 and 312. With such a configuration, since the heat generated by the tracker module 7C can be suppressed, the deterioration of the voltage output characteristics of the switched-capacitor circuit 20 and the supply modulator 30 can be suppressed. Therefore, the efficiency deterioration of the amplifier circuit that receives the power supply voltage from the tracker module 7C can be suppressed.

Note that it is sufficient that at least the switches and capacitors included in the switched-capacitor circuit 20 and the switches included in the supply modulator 30 are disposed on the module laminate 90. Further, it is sufficient that the switches included in the pre-regulator circuit 311 are disposed on the substrate 391 and that the switches included in the pre-regulator circuit 312 are disposed on the substrate 392. Further, the substrates 391 and 392 may be a single substrate in an exemplary aspect.

With the regulated voltage input terminals 125 and 126, since the regulated voltages generated by the pre-regulator circuits 311 and 312 are supplied from the outside of the tracker module 7C, the tracker module 7C including the switched-capacitor circuit 20 and the supply modulator 30 but not including the pre-regulator circuits 311 and 312 is not affected by the heat generated by the pre-regulator circuits 311 and 312. With such a configuration, since the heat generated by the tracker module 7C can be suppressed, the deterioration of the voltage output characteristics of the switched-capacitor circuit 20 and the supply modulator 30 can be suppressed. Therefore, the efficiency deterioration of the amplifier circuit that receives the power supply voltage from the tracker module 7C can be suppressed.

The tracker module 7C, the pre-regulator circuits 311 and 312, and the power amplifiers 81 to 83, 87, and 88 collectively form the communication device according to the present variation.

The power amplifier 82 can amplify a radio frequency signal of a band A received from an RFIC 3. The power amplifier 83 can amplify a radio frequency signal of a band B received from the RFIC 3. The power amplifier 81 can amplify a radio frequency signal of a band C received from the RFIC 3. The power amplifier 87 can amplify a radio frequency signal of a band D received from the RFIC 3. The power amplifier 88 can amplify a radio frequency signal of a band E received from the RFIC 3.

One of the power amplifiers 82 and 83 may amplify a radio frequency signal of 2G received from the RFIC 3.

The band A and the band D are included, for example, in an LB group, and the band B and the band E are included, for example, in an MHB group. The band C is included, for example, in a UHB group.

In the above configuration, the communication device according to the present variation can simultaneously transmit two radio frequency signals having different tracking modes (2 uplinks).

For example, by connecting the common terminal and the first selection terminal of the switch 70, the radio frequency signal of the band C can be transmitted from the power amplifier 81 in a digital ET mode, and the radio frequency signal of the band D or the band E can be transmitted from the power amplifier 87 or 88 in an APT mode.

For example, by connecting the common terminal and the second selection terminal of the switch 70, the radio frequency signal of the band C can be transmitted from the power amplifier 81 in a digital ET mode, and the radio frequency signal of the band A or the band B can be transmitted from the power amplifier 82 or 83 in an APT mode.

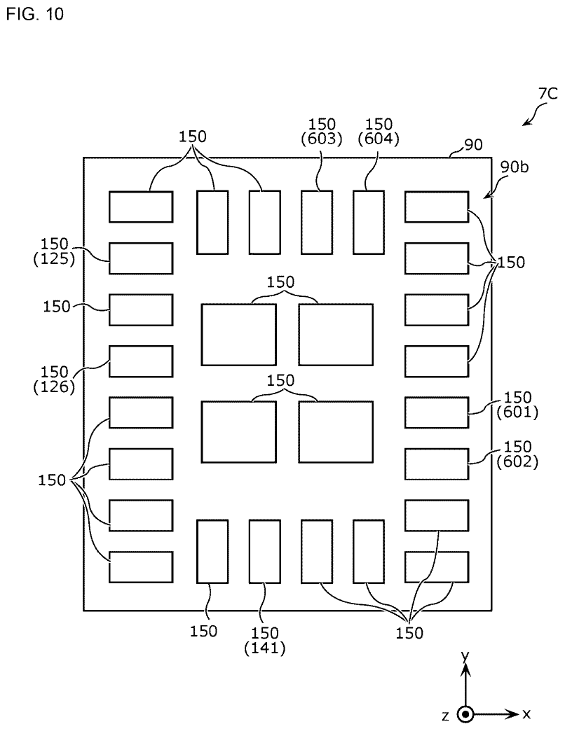

FIG. 10 is a plan view of the tracker module 7C according to Variation 3 and is obtained when a main surface 90b side of the module laminate 90 is viewed, in a transparent manner, from the positive direction of the z-axis. Note that a plan view of the tracker module 7C obtained when the main surface 90b side of the module laminate 90 is viewed, in a transparent manner, from the positive direction of the z-axis and a cross-sectional view of the tracker module 7C are substantially the same as the plan view and the cross-sectional view of the tracker module 7 according to the exemplary embodiment, and therefore are not shown. The tracker module 7C according to the present variation differs from the tracker module 7 according to the exemplary embodiment only in the arrangement configuration of the regulated voltage input terminals 125 and 126. Hereinafter, in the tracker module 7C according to the present variation, the same parts as those of the tracker module 7 according to the exemplary embodiment will be omitted, and only different parts will be mainly described.

External connection electrodes 150 are disposed on the main surface 90b. The regulated voltage input terminals 125 and 126, the control terminals 601 to 604, and the external connection terminal 141 are included in the external connection electrodes 150. Some of the plurality of external connection electrodes 150 are set to the ground potential.

The external connection electrodes 150 may be planar electrodes as shown in FIG. 10, or bump electrodes formed on the main surface 90b in various exemplary aspects.

In the tracker module 7C, the regulated voltage input terminals 125 and 126 are disposed on the main surface 90b. Further, switches (an SC switch portion 20A) and capacitors (capacitors C10, C20, C30, C40, C11, C12, C13, C14, C15, and C16) included in the switched-capacitor circuit 20 and switches (an OS switch portion 30A) included in the supply modulator 30 are disposed on a main surface 90a.

With such a configuration, since the regulated voltage input terminals 125 and 126, the switches and capacitors included in the switched-capacitor circuit 20, and the switches included in the supply modulator 30 are disposed on both sides of the module laminate 90, the size of the tracker module 7C can be reduced while also diffusing the heat generated by the tracker module 7C.

Further, when the module laminate 90 is viewed in plan view, the regulated voltage input terminals 125 and 126 overlap with at least some of the capacitors included in the switched-capacitor circuit 20.

With such a configuration, since the wiring lines for transmitting the regulated voltage to the capacitors in the switched-capacitor circuit 20 can be shortened, the voltage output characteristics of the switched-capacitor circuit 20 can be improved.

Further, the regulated voltage input terminals 125 and 126 are disposed on the outermost peripheral portion of the main surface 90b.

With such a configuration, since the wiring lines that transmit the regulated voltage generated by the pre-regulator circuits 311 and 312 disposed outside the tracker module 7C to the regulated voltage input terminals 125 and 126 can be shortened, the transmission loss of the regulated voltage can be reduced.

It is noted that the configuration of the tracker module 7C according to the present variation is an example and is not limited to such an example. For example, some of the capacitors, inductors, and resistor disposed on the main surface 90a may be formed in the module laminate 90 in various exemplary aspects.

### [1.7 Implementation Configuration of Communication Device 6]

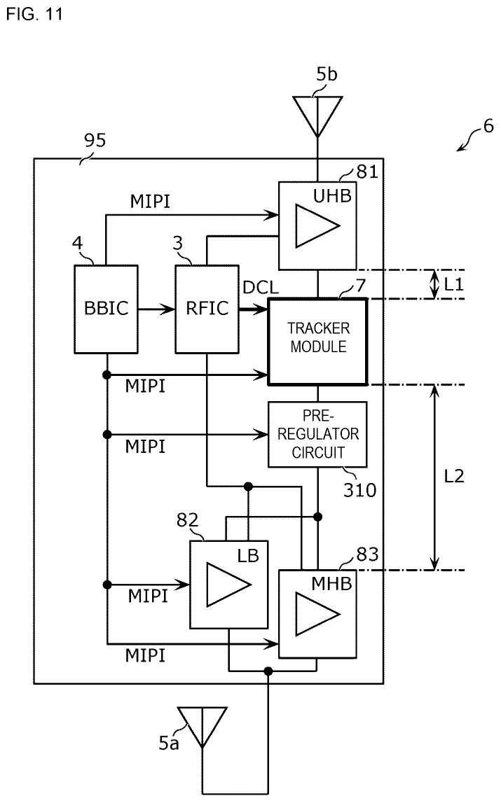

Next, the implementation configuration of the communication device 6 according to the present exemplary embodiment will be described with reference to FIG. 11.

FIG. 11 is an implementation configuration diagram of the communication device 6 according to the exemplary embodiment. The communication device 6 includes a mother board 95, a tracker module 7, a pre-regulator circuit 310, power amplifiers 81, 82, and 83, an RFIC 3, a BBIC 4, and antennas 5a and 5b.

The tracker module 7, the pre-regulator circuit 310, the power amplifiers 81, 82, and 83, the RFIC 3, and the BBIC 4 are disposed in the mother board 95.

The mother board 95 is a board on which the tracker module 7, the pre-regulator circuit 310, the power amplifiers 81, 82, and 83, the RFIC 3, and the BBIC 4 are mounted. For example, an LTCC substrate, an HTCC substrate, a component-embedded board, a substrate having an RDL, a printed circuit board, or the like is used as the mother board 95.

The pre-regulator circuit 310 is configured to convert an input voltage into a regulated voltage.

The power amplifier 81 is an example of a second power amplifier and is connected between the RFIC 3 and the antenna 5b. Further, the power amplifier 81 is connected to the tracker module 7.

The power amplifiers 82 and 83 are an example of a first power amplifier and are connected between the RFIC 3 and the antenna 5a. The power amplifiers 82 and 83 are connected to the pre-regulator circuit 310 without the tracker module 7 interposed therebetween.

With the configuration described above, since the circuit components of the pre-regulator circuit 310 and the circuit components of the switched-capacitor circuit 20 and the supply modulator 30 are disposed on different substrates, the tracker module 7 including the switched-capacitor circuit 20 and the supply modulator 30 but not including the pre-regulator circuit 310 is not affected by the heat generated by the pre-regulator circuit 310. With such a configuration, since the heat generated by the tracker module 7 can be suppressed, the deterioration of the voltage output characteristics of the switched-capacitor circuit 20 and the supply modulator 30 can be suppressed. Therefore, the efficiency deterioration of the power amplifier 81 that receives the power supply voltage from the tracker module 7 can be suppressed.

For purposes of this disclosure, when the mother board 95 is viewed in plan view, the distance between the tracker module 7 and the power amplifier 81 is smaller than the distance between the tracker module 7 and the power amplifiers 82 and 83.

With such a configuration, since the wiring line for supplying a power supply voltage V_{T1} in the digital ET mode to the power amplifier 81 can be shortened, the deterioration of the output characteristics of the power supply voltage V_{T1} in the digital ET mode can be suppressed, and the efficiency deterioration of the power amplifier 81 that receives the power supply voltage from the tracker module 7 can be suppressed.

### [1.8 Technical Effects]

As described above, the tracker module 7 according to the present exemplary embodiment includes: the module laminate 90 that is separate from the substrate 390 on which the switches included in the pre-regulator circuit 310 configured to convert an input voltage into a regulated voltage are disposed; the switched-capacitor circuit 20 configured to generate a plurality of discrete voltages based on the regulated voltage, and the supply modulator 30 configured to selectively output at least one of the plurality of discrete voltages to an amplifier. The switches and the capacitors included in the switched-capacitor circuit 20 and the switches included in the supply modulator 30 are disposed on the module laminate 90.

With such a configuration, since the circuit components of the pre-regulator circuit 310 and the circuit components of the switched-capacitor circuit 20 and the supply modulator 30 are disposed on different substrates, the tracker module 7 including the switched-capacitor circuit 20 and the supply modulator 30 but not including the pre-regulator circuit 310 is not affected by the heat generated by the pre-regulator circuit 310. With such a configuration, since the heat generated by the tracker module 7 can be suppressed, the deterioration of the voltage output characteristics of the switched-capacitor circuit 20 and the supply modulator 30 can be suppressed. Therefore, the efficiency deterioration of the amplifier circuit 2 that receives the power supply voltage from the tracker module 7 can be suppressed.

Further, the tracker module 7 according to the present embodiment includes: the switched-capacitor circuit 20 configured to generate a plurality of discrete voltages based on the first regulated voltage regulated by the first converter; the supply modulator 30 configured to selectively output at least one of the plurality of discrete voltages to the power amplifier 81; the module laminate 90 on which the switches and the capacitors included in the switched-capacitor circuit 20 and the switches included in the supply modulator 30 are disposed; and the externally connectable regulated voltage input terminals 121 to 124 that are disposed on the module laminate 90 and that receive the first regulated voltage.

With such a configuration, since the first regulated voltage generated by the pre-regulator circuit 310 is supplied from the outside of the tracker module 7, the tracker module 7 including the switched-capacitor circuit 20 and the supply modulator 30 but not including the pre-regulator circuit 310 is not affected by the heat generated by the pre-regulator circuit 310. With such a configuration, since the heat generated by the tracker module 7 can be suppressed, the deterioration of the voltage output characteristics of the switched-capacitor circuit 20 and the supply modulator 30 can be suppressed. Therefore, the efficiency deterioration of the amplifier circuit 2 that receives the power supply voltage from the tracker module 7 can be suppressed.

Further, for example, the tracker module 7 may further include the externally connectable control terminals 603 and 604 that are disposed on the module laminate 90 and that receive the digital control signal corresponding to one of the plurality of discrete voltages.

Further, for example, in the tracker module 7, all circuit components included in the switched-capacitor circuit 20 and all circuit components included in the supply modulator 30 may be disposed on the module laminate 90.

Further, for example, in the tracker module 7, the module laminate 90 may have the main surfaces 90a and 90b facing each other, the regulated voltage input terminals 121 to 124 may be disposed on the main surface 90b, and at least one of the switches and capacitors included in the switched-capacitor circuit 20 and the switches included in the supply modulator 30 may be disposed on the main surface 90a.

With such a configuration, since the regulated voltage input terminals 121 to 124, the switches and capacitors included in the switched-capacitor circuit 20, and the switches included in the supply modulator 30 are disposed on both sides of the module laminate 90, the size of the tracker module 7 can be reduced while also diffusing the heat generated by the tracker module 7.

Further, for example, in the tracker module 7, the capacitors included in the switched-capacitor circuit 20 are disposed on the main surface 90a, and when the module laminate 90 is viewed in plan view, the regulated voltage input terminals 121 to 124 may overlap with at least some of the capacitors included in the switched-capacitor circuit 20.

With such a configuration, since the wiring lines for transmitting the regulated voltage to the capacitors in the switched-capacitor circuit 20 can be shortened, the voltage output characteristics of the switched-capacitor circuit 20 can be improved.

Further, for example, in the tracker module 7A according to Variation 1, the switches included in the switched-capacitor circuit 20 and the switches included in the supply modulator 30 may be included in the integrated circuit 80, and the integrated circuit 80 may be disposed on the main surface 90b in various exemplary aspects.

With such a configuration, since the switches included in the switched-capacitor circuit 20, the switches included in the supply modulator 30 (the integrated circuit 80), and the capacitors included in the switched-capacitor circuit 20 are disposed on both sides of the module laminate 90, the size of the tracker module 7A can be reduced.

Further, for example, in the tracker module 7, the regulated voltage input terminals 121 to 124 may be disposed on the outermost peripheral portion of the main surface 90b in various exemplary aspects.

With such a configuration, since the wiring lines that transmit the regulated voltage generated by the pre-regulator circuit 310 disposed outside the tracker module 7 to the regulated voltage input terminals 121 to 124 can be shortened, the transmission loss of the regulated voltage can be reduced.

Further, for example, in the tracker module 7B according to Variation 2, the switches included in the switched-capacitor circuit 20 and the switches included in the supply modulator 30 are included in the integrated circuit 80, the capacitors included in the switched-capacitor circuit 20 are included in the integrated circuit 89 made of a silicon substrate, the integrated circuit 80 is disposed on the main surface 90a, and the integrated circuit 89 is disposed on the main surface 90b.

With such a configuration, since the switches included in the switched-capacitor circuit 20 are integrated, and the integrated circuits 80 and 88 are disposed on both sides of the module laminate 90, the size of the tracker module 7B can be reduced.

Further, for example, the tracker module 7B according to Variation 2 further includes the shield electrode layer 93 covering at least a portion of the surface of the tracker module 7B, the integrated circuit 80 has the third main surface and the fourth main surface facing each other, the integrated circuit 89 has the fifth main surface and the sixth main surface facing each other, the third main surface faces the main surface 90a, the fourth main surface is in contact with the shield electrode layer 93, the fifth main surface faces the main surface 90b, and the sixth main surface may be exposed.

With such a configuration, since the integrated circuit 89 has an IPD structure, the sixth main surface side can be polished, so that the integrated circuit can be made thin. Further, the integrated circuit 80 can expose the fourth main surface from the resin member 91 by polishing the fourth main surface side, and the exposed fourth main surface can be brought into contact with the shield electrode layer 93. Therefore, the shielding property of the integrated circuit 80 is enhanced, the operating performance of each switch included in the integrated circuit 80 is improved, and the height of the tracker module 7B can be reduced.

Further, for example, in the tracker module 7B according to Variation 2, when the module laminate 90 is viewed in plan view, the regulated voltage input terminals 121 to 124 need not overlap with the integrated circuit 80.

With such a configuration, the heat flowing in via the regulated voltage input terminals 121 to 124 due to the regulated voltage generated by the pre-regulator circuit 310 can be suppressed from diffusing into the integrated circuit 80. Therefore, the operating performance of each switch included in the integrated circuit 80 is improved.

Further, for example, the tracker module 7C according to Variation 3 includes: the switched-capacitor circuit 20 configured to generate a plurality of discrete voltages based on the first regulated voltage regulated by the first converter or the second regulated voltage regulated by the second converter; the supply modulator 30 configured to selectively output at least one of the plurality of discrete voltages to the power amplifier 81; the module laminate 90 on which the switches and the capacitors included in the switched-capacitor circuit 20 and the switches included in the supply modulator 30 are disposed; the externally connectable regulated voltage input terminal 125 that is disposed on the module laminate 90 and that receives the first regulated voltage; the externally connectable regulated voltage input terminal 126 that is disposed on the module laminate 90 and that receives the second regulated voltage; and the switch 70 that is disposed on the module laminate 90 and that switches between connection of the regulated voltage input terminal 125 to the switched-capacitor circuit 20 and connection of the regulated voltage input terminal 126 to the switched-capacitor circuit 20.

With such a configuration, since the first regulated voltage and the second regulated voltage are supplied from the outside of the tracker module 7C, the tracker module 7C is not affected by the heat generated by pre-regulator circuits 311 and 312. With such a configuration, since the heat generated by the tracker module 7C can be suppressed, the deterioration of the voltage output characteristics of the switched-capacitor circuit 20 and the supply modulator 30 can be suppressed. Therefore, the efficiency deterioration of the amplifier circuit that receives the power supply voltage from the tracker module 7C can be suppressed.

Further, for example, in the tracker module 7C according to Variation 3, the module laminate 90 has the main surfaces 90a and 90b facing each other, and at least one of the switches and capacitors included in the switched-capacitor circuit 20 and the switches included in the supply modulator 30 may be disposed on the main surface 90a, and the regulated voltage input terminals 125 and 126 may be disposed on the main surface 90b in various exemplary aspects.

With such a configuration, since the regulated voltage input terminals 125 and 126, the switches and capacitors included in the switched-capacitor circuit 20, and the switches included in the supply modulator 30 are disposed on both sides of the module laminate 90, the size of the tracker module 7C can reduced while also diffusing the heat generated by the tracker module 7C.

Further, for example, in the tracker module 7C according to Variation 3, the capacitors included in the switched-capacitor circuit 20 may be disposed on the main surface 90a, and each of the regulated voltage input terminals 125 and 126 may overlap with at least some of the capacitors included in the switched-capacitor circuit 20 when the module laminate 90 is viewed in plan view.

With such a configuration, since the wiring lines for transmitting the regulated voltage to the capacitors in the switched-capacitor circuit 20 can be shortened, the voltage output characteristics of the switched-capacitor circuit 20 can be improved.

Further, for example, in the tracker module 7C according to Variation 3, each of the regulated voltage input terminals 125 and 126 may be disposed on the outermost peripheral portion of the main surface 90b.

With such a configuration, since the wiring lines that transmit the regulated voltage generated by the pre-regulator circuits 311 and 312 disposed outside the tracker module 7C to the regulated voltage input terminals 125 and 126 can be shortened, the transmission loss of the regulated voltage can be reduced.

Further, the communication device 6 according to the present embodiment includes the tracker module 7, the pre-regulator circuit 310 connected to the tracker module 7 and configured to convert an input voltage into a regulated voltage, the power amplifiers 82 and 83 connected to the pre-regulator circuit 310 without the tracker module 7 interposed therebetween, and the power amplifier 81 connected to the tracker module 7.

With such a configuration, the tracker module 7 not including the pre-regulator circuit 310 is not affected by the heat generated by the pre-regulator circuit 310. With such a configuration, since the heat generated by the tracker module 7 can be suppressed, the deterioration of the voltage output characteristics of the switched-capacitor circuit 20 and the supply modulator 30 can be suppressed. Therefore, the efficiency deterioration of the power amplifier 81 that receives the power supply voltage from the tracker module 7 can be suppressed.

Further, for example, the communication device 6 further includes the mother board 95 on which the tracker module 7, the pre-regulator circuit 310, and the power amplifiers 81 to 83 are disposed, and when the mother board 95 is viewed in plan view, the distance between the tracker module 7 and the power amplifier 81 may be smaller than the distance between the tracker module 7 and the power amplifiers 82 and 83.

With such a configuration, since the wiring line for supplying the power supply voltage in the digital ET mode to the power amplifier 81 can be shortened, the deterioration of the output characteristics of the power supply voltage in the digital ET mode can be suppressed, and the efficiency deterioration of the power amplifier 81 that receives the power supply voltage from the tracker module 7 can be suppressed.

### Additional Exemplary Embodiments

The tracker module and the communication device according to the exemplary aspects of the present disclosure have been described above based on the embodiment and variations. However, the tracker module and the communication device described herein are not limited to the embodiment and variations described above. The present disclosure also includes other embodiments realized by combining any of the components in the embodiment and variations described above, variations obtained by applying various variations conceived by those skilled in the art to the embodiment and variations described above without departing from the spirit of the present disclosure, and various devices incorporating the tracker module or the communication device described above.

For example, other circuit elements, wiring lines, and/or the like may be inserted between the paths connecting the circuit elements and the signal paths disclosed in the drawings in the circuit configurations of various circuits according to the embodiment and variations described above.

The exemplary aspects of the present disclosure, as a tracker module that supplies a voltage to a power amplifier and a communication device that includes the power amplifier and the tracker module, can be widely used in communication devices such as a mobile phone.

### REFERENCE SIGNS LIST

1 tracker circuit
2 amplifier circuit
3 RFIC
4 BBIC
5a, 5b antenna
6 communication device
7, 7A, 7B, 7C tracker module
20 switched-capacitor circuit
20A SC switch portion
30 supply modulator
30A OS switch portion
40 filter circuit
60 digital control circuit
61 first controller
62 second controller
70, 71 switch
80, 89 integrated circuit
81, 82, 83, 87, 88 power amplifier
84, 85, 86 filter
90 module laminate
90a, 90b main surface
91, 92 resin member
93 shield electrode layer
95 mother board
110, 131, 132, 133, 134, 140 input terminal
111, 112, 113, 114, 130 output terminal
115, 116 inductor connection terminal
117, 120, 135, 601, 602, 603, 604 control terminal
121, 122, 123, 124, 125, 126 regulated voltage input terminal
141 external connection terminal
150 external connection electrode
310, 311, 312 pre-regulator circuit
350 DC power source
390, 391, 392 substrate

What is claimed:

1. A tracker module comprising:
a module laminate separate from a substrate on which a switch included in a pre-regulator circuit is disposed;
a switched-capacitor circuit configured to generate a plurality of discrete voltages based on a regulated voltage provided by the pre-regulator circuit; and
a supply modulator configured to selectively output at least one of the plurality of discrete voltages to an amplifier,
wherein the switched-capacitor circuit includes a switch and a capacitor and the supply modulator includes a switch that are each disposed on the module laminate.

2. The tracker module according to claim 1, further comprising an externally connectable digital control terminal that is disposed on the module laminate and that is configured to receive a digital control signal corresponding to one of the plurality of discrete voltages.

3. The tracker module according to claim 1, wherein all circuit components included in the switched-capacitor circuit and all circuit components included in the supply modulator are disposed on the module laminate.

4. A tracker module comprising:
a switched-capacitor circuit configured to generate a plurality of discrete voltages based on a first regulated voltage regulated by a first converter;
a supply modulator configured to selectively output at least one of the plurality of discrete voltages to an amplifier;
a module laminate; and
an externally connectable first regulated voltage input terminal that is disposed on the module laminate and that receives the first regulated voltage,
wherein the switched-capacitor circuit includes a switch and a capacitor and the supply modulator includes a switch that are each disposed on the module laminate.

5. The tracker module according to claim 4, wherein:
the module laminate has a first main surface and a second main surface that oppose each other,
the first regulated voltage input terminal is disposed on the second main surface, and
at least one of the switch and the capacitor of the switched-capacitor circuit and the switch of the supply modulator is disposed on the first main surface.

6. The tracker module according to claim 5, wherein:
the capacitor of the switched-capacitor circuit is disposed on the first main surface, and
the first regulated voltage input terminal overlaps with at least a portion of the capacitor of the switched-capacitor circuit in a plan view of the module laminate.

7. The tracker module according to claim 6, wherein the switch of the switched-capacitor circuit and the switch of the supply modulator are included in a first semiconductor IC that is disposed on the second main surface.

8. The tracker module according to claim 5, wherein the first regulated voltage input terminal is disposed on an outermost peripheral portion of the second main surface.

9. The tracker module according to claim 6, wherein:
the switch of the switched-capacitor circuit and the switch of the supply modulator are included in a second semiconductor IC,
the capacitor of the switched-capacitor circuit is included in an integrated passive device comprising a silicon substrate,
the second semiconductor IC is disposed on the first main surface, and
the integrated passive device is disposed on the second main surface.

10. The tracker module according to claim 9, further comprising:
a shield electrode layer covering at least a portion of a surface of the tracker module,
wherein:
the second semiconductor IC has a third main surface and a fourth main surface,
the integrated passive device has a fifth main surface and a sixth main surface,
the third main surface faces the first main surface,
the fourth main surface contacts the shield electrode layer,
the fifth main surface faces the second main surface, and
the sixth main surface is externally exposed from the tracker module.

11. The tracker module according to claim 9, wherein the first regulated voltage input terminal does not overlap with the second semiconductor IC in the plan view of the module laminate.

12. The tracker module according to claim 4, further comprising:
an externally connectable second regulated voltage input terminal that is disposed on the module laminate and that is configured to receive a second regulated voltage regulated by a second converter; and
a first switch that is disposed on the module laminate and that is configured to switch between connecting the first regulated voltage input terminal to the switched-capacitor circuit and connecting of the second regulated voltage input terminal to the switched-capacitor circuit,
wherein the switched-capacitor circuit is configured to generate the plurality of discrete voltages based on the first regulated voltage or the second regulated voltage.

13. The tracker module according to claim 12, wherein:
the module laminate has a first main surface and a second main surface that oppose each other, and
the second regulated voltage input terminal is disposed on the second main surface of the module laminate.

14. The tracker module according to claim 13, wherein:
the capacitor of the switched-capacitor circuit is disposed on the first main surface of the module laminate, and
each of the first regulated voltage input terminal and the second regulated voltage input terminal overlaps with at least a portion of the capacitor of the switched-capacitor circuit in a plan view of the module laminate.

15. The tracker module according to claim 13, wherein each of the first regulated voltage input terminal and the second regulated voltage input terminal is disposed on an outermost peripheral portion of the second main surface.

16. The tracker module according to claim 4, further comprising an externally connectable digital control terminal that is disposed on the module laminate and that is configured to receive a digital control signal corresponding to one of the plurality of discrete voltages.

17. The tracker module according to claim 4, wherein all circuit components included in the switched-capacitor circuit and all circuit components included in the supply modulator are disposed on the module laminate.

18. A communication device comprising:
the tracker module according to claim 1;
a pre-regulator circuit connected to the tracker module and configured to convert an input voltage into the regulated voltage;
a first power amplifier connected to the pre-regulator circuit without the tracker module interposed therebetween; and
a second power amplifier connected to the tracker module.

19. The communication device according to claim 18, further comprising:
a substrate on which the tracker module, the pre-regulator circuit, the first power amplifier, and the second power amplifier are disposed,
wherein a distance between the tracker module and the second power amplifier is smaller than a distance between the tracker module and the first power amplifier in a plan view of the substrate.

20. A communication device comprising:
the tracker module according to claim 4;
a pre-regulator circuit connected to the tracker module and configured to convert an input voltage into the first regulated voltage;
a first power amplifier connected to the pre-regulator circuit without the tracker module interposed therebetween; and
a second power amplifier connected to the tracker module.
